(19) United States
(12) Patent Application Publication
(10) Pub. No.: US 2024/0313038 A1
(43) Pub. Date: Sep. 19, 2024

(54) DISPLAY DEVICE AND METHOD OF FABRICATING THE SAME

(71) Applicant: Samsung Display Co., LTD., Yongin-si (KR)

(72) Inventors: Ju Won YOON, Yongin-si (KR); Jung Hun NOH, Yongin-si (KR)

(21) Appl. No.: 18/440,823

(22) Filed: Feb. 13, 2024

(30) Foreign Application Priority Data
Mar. 15, 2023 (KR) 10-2023-0033679

(51) Int. Cl. H01L 27/15

(52) U.S. Cl. CPC H01L 27/156

(57) ABSTRACT

A display device includes a semiconductor circuit substrate having a display area and a non-display area and having a plurality of pixel circuit units and a plurality of light emitting element layers including two or more layers stacked on the display area of the semiconductor circuit substrate, each of the two or more layers including a plurality of light emitting elements, wherein the plurality of light emitting elements at a same layer of the plurality of light emitting element layers is configured to emit a same color light and the light emitting elements at different layers of the plurality of light emitting element layers are configured to emit different color lights, and the plurality of light emitting elements at the same layer is connected to a same common electrode and the light emitting elements at the different layers are connected to different common electrodes.

### CROSS-REFERENCE TO RELATED APPLICATION

The present application claims priority to and the benefit of Korean Patent Application No. 10-2023-0033679, filed on Mar. 15, 2023, in the Korean Intellectual Property Office, the entire content of which is incorporated by reference herein.

### BACKGROUND

### 1. Field

The present disclosure relates to a display device and a method of fabricating the same.

### 2. Description of Related Art

As the information society develops, the demand for display devices for displaying images has increased and diversified. The display devices may be flat panel display devices such as liquid crystal displays (LCDs), field emission displays (FEDs), or light emitting displays (LEDs).

Light emitting display devices may be implemented as organic light emitting display devices including organic light emitting diode elements as light emitting elements, inorganic light emitting display devices including inorganic semiconductor elements as light emitting elements, and micro light emitting diode display devices including micro light emitting diode elements as light emitting elements. In this case, in the micro light emitting diode display device, micro light emitting diode elements are bonded to pixel electrodes, and thus, it is desirable to decrease resistance of the pixel electrodes.

### SUMMARY

Aspects and features of the present disclosure provide a method of fabricating a display device capable of concurrently (e.g., simultaneously) bonding a plurality of light emitting elements for emitting the same color light to a semiconductor circuit substrate through an alignment-free method.

Aspects and features of the present disclosure also provide a display device in which a plurality of light emitting elements for emitting the same color light are disposed at the same layer and light for emitting elements emitting different lights are disposed at different layers.

However, aspects and features of the present disclosure are not restricted to the one set forth herein. The above and other aspects and features of the present disclosure will become more apparent to one of ordinary skill in the art to which the present disclosure pertains by referencing the detailed description of the present disclosure given below.

According to one or more embodiments, a display device includes a semiconductor circuit substrate having a display area and a non-display area and having a plurality of pixel circuit units and a plurality of light emitting element layers including two or more layers stacked on the display area of the semiconductor circuit substrate, each of the two or more layers including a plurality of light emitting elements, wherein the plurality of light emitting elements at a same layer of the plurality of light emitting element layers is configured to emit a same color light and the light emitting elements at different layers of the plurality of light emitting element layers are configured to emit different color lights, and the plurality of light emitting elements at the same layer of the plurality of light emitting element layers is connected to a same common electrode and the light emitting elements at the different layers of the plurality of light emitting element layers is connected to different common electrodes.

The display device further includes a plurality of pixel electrodes connected to the plurality of pixel circuit units, respectively and contact electrodes on one surfaces of the light emitting elements and connected to the pixel electrodes.

Each of the plurality of light emitting element layers includes the pixel electrode, the plurality of light emitting elements on the pixel electrode, a contact electrode on one surface of each of the plurality of light emitting elements, a first insulating layer covering side surfaces of the plurality of light emitting elements between the plurality of light emitting elements, and a common electrode on upper surfaces of the light emitting elements and an upper surface of the first insulating layer.

The common electrode is on upper surfaces of the plurality of light emitting elements of the same layer.

The display device further includes a second insulating layer between the plurality of light emitting element layers.

The first insulating layer and the second insulating layer include openings overlapping upper surfaces of the light emitting elements located therebelow, and a width of the openings is greater than a width of the light emitting elements.

The pixel electrodes are electrically connected to corresponding pixel circuit units through contact holes in the first insulating layer and the second insulating layer located below the pixel electrodes.

The protective electrodes are formed on the contact holes in the insulating layers located below the pixel electrodes, and the pixel electrodes cover the protective electrodes.

The protective electrode has an etching selectivity different from that of the pixel electrode and includes a conductive material.

The contact electrode is on the pixel electrode.

The light emitting elements are randomly arranged on the pixel electrode. The pixel electrode is in contact with side surfaces of the contact electrode.

The contact electrode protrudes outward of the light emitting element in a first direction, and the pixel electrode covers the contact electrode protruding outward.

The common electrodes of the light emitting elements at the different layers are connected to each other, are separated from each other, or are partially connected to each other in the non-display area.

According to one or more embodiments, a display device includes a semiconductor circuit substrate having a plurality of pixel circuit units, a first insulating layer on a display area of the semiconductor circuit substrate, a first light emitting element layer including a first pixel electrode, a first light emitting element configured to emit first light, and a first common electrode that are sequentially arranged on the first insulating layer, a second insulating layer on the first light emitting element layer and a second light emitting element layer including a second pixel electrode, a second light emitting element configured to emit second light, and a second common electrode that are sequentially arranged on the second insulating layer.

The display device further includes a third insulating layer on the second light emitting element layer, a third light emitting element layer including a third pixel electrode, a third light emitting element configured to emit third light, and a third common electrode that are sequentially arranged on the third insulating layer and a fourth insulating layer on the third light emitting element layer.

The first insulating layer includes contact holes overlapping the first pixel electrode, the second pixel electrode, and the third pixel electrode and penetrating through the first insulating layer, the second insulating layer includes contact holes overlapping the second pixel electrode and the third pixel electrode and penetrating through the second insulating layer, the third insulating layer includes a contact hole overlapping the third pixel electrode and penetrating through the third insulating layer, and the display device further includes first protective electrodes on the first insulating layer and covering the contact holes penetrating through the first insulating layer, second protective electrodes on the second insulating layer and covering the contact holes penetrating through the second insulating layer, and a third protective electrode on the third insulating layer and covering the contact hole penetrating through the third insulating layer.

According to one or more embodiments, a method of fabricating a display device includes forming a first insulating layer on a semiconductor circuit substrate, the first insulating layer having contact holes and the semiconductor circuit substrate having a plurality of pixel circuit units, forming a first light emitting element layer including a first pixel electrode, a first light emitting element configured to emit first light, and a first common electrode that are sequentially arranged on the first insulating layer, forming a second insulating layer on the first light emitting element layer and forming a second light emitting element layer including a second pixel electrode, a second light emitting element configured to emit second light, and a second common electrode that are sequentially arranged on the second insulating layer.

The method of fabricating a display device further includes forming a third insulating layer on the second light emitting element layer, forming a third light emitting element layer including a third pixel electrode, a third light emitting element configured to emit third light, and a third common electrode that are sequentially arranged on the third insulating layer, and forming a fourth insulating layer on the third light emitting element layer.

The forming of the first light emitting element layer includes forming first protective electrodes on the first insulating layer, the first protective electrodes covering the contact holes and being connected to the pixel circuit units, applying a pixel electrode material onto the first insulating layer on which the first protective electrodes are formed, bonding a base substrate on which the first light emitting elements are formed to the semiconductor circuit substrate and separating the base substrate, forming a pixel electrode in contact with the first light emitting element of a first emission area through a photoresist process, forming a fourth insulating layer covering the pixel electrode and side surfaces of the first light emitting element and forming the first common electrode covering the fourth insulating layer and an upper surface of the first light emitting element.

The forming of the fourth insulating layer, a contact hole penetrating through the fourth insulating layer is formed, and in the forming of the first common electrode, a first bridge electrode covering the contact hole penetrating through the fourth insulating layer is formed, the first bridge electrode includes a same material as the first, second, and third common electrodes and spaced from the first, second, and third common electrodes.

The protective electrode has an etching selectivity different from that of the pixel electrode and includes a conductive material.

The forming of the first light emitting element layer includes forming a sacrificial layer on the first insulating layer by covering the contact holes of a second emission area and a third emission area with a sacrificial material, bonding a base substrate on which the first light emitting elements are formed to the semiconductor circuit substrate and separating the base substrate, removing the sacrificial material, forming a pixel electrode and connection electrodes through a photoresist process, the pixel electrode in contact with the first light emitting element of a first emission area on side surfaces of the first light emitting element and the connection electrodes covering the contact holes of the second emission area and the third emission area, forming a fourth insulating layer covering the pixel electrode, the connection electrodes, and the side surfaces of the first light emitting element and forming the first common electrode covering the fourth insulating layer and an upper surface of the first light emitting element.

With a display device according to embodiments, it is possible to simultaneously bond a plurality of light emitting elements emitting the same light to a semiconductor circuit substrate through an alignment-free method.

However, the effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a layout diagram illustrating a display device according to one or more embodiments;

FIG. 2 is a layout diagram illustrating an area A of FIG. 1 in detail;

FIG. 3 is a layout diagram illustrating sub-pixels of a display panel according to one or more embodiments;

FIG. 4 is a cross-sectional view illustrating an example of the display panel taken along the line A-A′ of FIG. 2;

FIG. 5 is an enlarged view of a display panel of a display area of FIG. 4;

FIG. 6 is an enlarged view of a light emitting element of FIG. 5;

FIG. 7 is a plan view of a first light emitting element layer according to one or more embodiments of the present disclosure;

FIG. 8 is a plan view of first and second light emitting element layers according to one or more embodiments of the present disclosure;

FIG. 9 is a plan view of first to third light emitting element layers according to one or more embodiments of the present disclosure;

FIG. 10 is an enlarged view of the display panel of the display area of FIG. 4 according to one or more embodiments;

FIG. 11 is a plan view of a first light emitting element layer of FIG. 10;

FIG. 12 is a plan view of first and second light emitting element layers of FIG. 10;

FIG. 13 is a plan view of first to third light emitting element layers of FIG. 10;

FIG. 14 is an enlarged view of the display panel of the display area of FIG. 4 according to one or more embodiments;

FIG. 15 is an enlarged view of the display panel of the display area of FIG. 4 according to one or more embodiments;

FIG. 16 is a cross-sectional view illustrating an example of a display panel taken along the line A-A′ of FIG. 2 according to another embodiment of the present disclosure;

FIG. 17 is a cross-sectional view illustrating an example of a display panel taken along the line A-A′ of FIG. 2 according to one or more embodiments of the present disclosure;

FIG. 18 is a flowchart illustrating a method of fabricating a display device according to one or more embodiments of the present disclosure;

FIGS. 19 to 45 are cross-sectional views for describing a method of fabricating a display device according to one or more embodiments;

FIG. 46 is a flowchart illustrating a method of fabricating a display device according to one or more embodiments of the present disclosure; and

FIGS. 47 to 62 are cross-sectional views for describing the method of fabricating a display device according to one or more embodiments.

FIG. 63 is an example diagram schematically showing a virtual reality device including a display device according to one or more embodiments.

FIG. 64 is an example diagram schematically showing a smart device including a display device according to one or more embodiments.

FIG. 65 is a diagram of an example schematically showing a vehicle including a display device according to one or more embodiments.

FIG. 66 is a diagram of an example schematically showing a transparent display device including a display device according to one or more embodiments.

### DETAILED DESCRIPTION

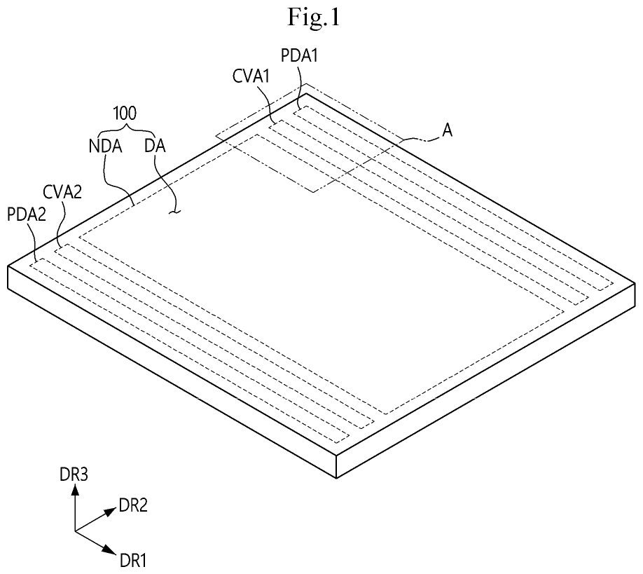

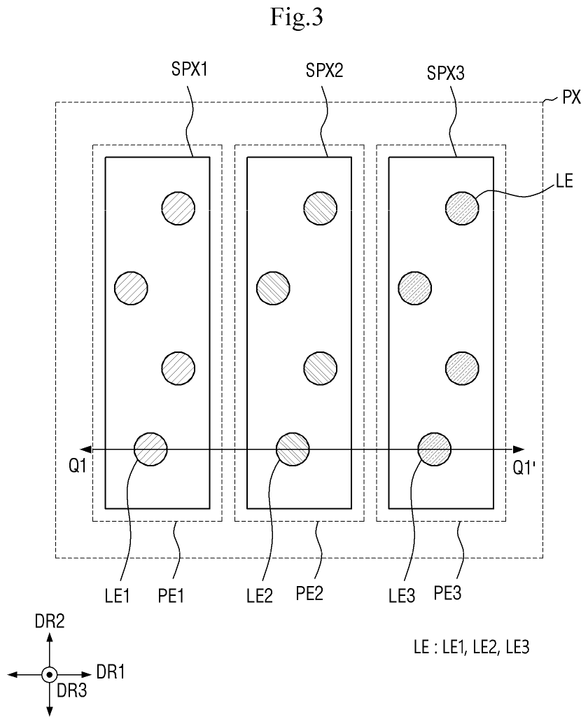

Referring to FIGS. 1 to 3, a display device 10 according to one or more embodiments includes a display panel 100 including a display area DA and a non-display area NDA along an edge or periphery of the display area DA.

The display panel 100 may have a rectangular shape, in a plan view, having long sides in the first direction DR1 and short sides in the second direction DR2. However, the shape of the display panel 100 in a plan view is not limited thereto, and the display panel 100 may have polygonal shapes other than the rectangular shape, a circular shape, an elliptical shape, or an irregular shape in a plan view.

The display area DA may be an area in which an image is displayed, and the non-display area NDA may be an area in which no image is displayed. A shape of the display area DA in a plan view may follow the shape of the display panel 100 in a plan view. It has been illustrated in FIG. 1 that the shape of the display area DA in a plan view is a rectangular shape. The display area DA may be disposed in a central area of the display panel 100. The non-display area NDA may be disposed around the display area DA. The non-display area NDA may be disposed to surround the display area DA.

The display area DA of the display panel 100 may include a plurality of pixels PX. The pixel PX may be defined as a minimum light emitting unit capable of displaying white light.

Each of the plurality of pixels PX may include a plurality of sub-pixels SPX1, SPX2, and SPX3 emitting light. It has been illustrated in one or more embodiments of the present disclosure that each of the plurality of pixels PX includes three sub-pixels SPX1, SPX2, and SPX3, but the present disclosure is not limited thereto. For example, each of the plurality of pixels PX may include four sub-pixels. The plurality of sub-pixels SPX1, SPX2, and SPX3 may include a first sub-pixel SPX1, a second sub-pixel SPX2, and a third sub-pixel SPX3.

The first sub-pixel SPX1 may include a plurality of first light emitting elements LE1 emitting first light. The first light may be light of a red wavelength band. The red wavelength band may be approximately 600 nm to 750 nm, but the present disclosure is not limited thereto.

The second sub-pixel SPX2 may include a plurality of second light emitting elements LE2 emitting second light. The second light may be light of a green wavelength band. The green wavelength band may be approximately 480 nm to 560 nm, but the present disclosure is not limited thereto.

The third sub-pixel SPX3 may include a plurality of third light emitting elements LE3 emitting third light. The third light may be light of a blue wavelength band. The blue wavelength band may be approximately 370 nm to 460 nm, but the present disclosure is not limited thereto.

The first sub-pixels SPX1, the second sub-pixels SPX2, and the third sub-pixels SPX3 may be alternately arranged along the first direction DR1. For example, the first sub-pixels SPX1, the second sub-pixels SPX2, and the third sub-pixels SPX3 may be disposed in order of the first sub-pixel SPX1, the second sub-pixel SPX2, and the third sub-pixel SPX3 in the first direction DR1. The first sub-pixels SPX1 may be arranged along the second direction DR2. The second sub-pixels SPX2 may be arranged along the second direction DR2. The third sub-pixels SPX3 may be arranged along the second direction DR2, but the present disclosure is not limited thereto.

The non-display area NDA may include a first common voltage supply area CVA1, a second common voltage supply area CVA2, a first pad part PDA1, and a second pad part PDA2.

The first common voltage supply area CVA1 may be disposed between the first pad part PDA1 and the display area DA. The second common voltage supply area CVA2 may be disposed between the second pad part PDA2 and the display area DA. Each of the first common voltage supply area CVA1 and the second common voltage supply area CVA2 may include a plurality of common contact electrode CCE connected to a common electrode CE. A common voltage may be supplied to the common electrode CE through the plurality of common contact electrode CCE.

The plurality of common contact electrode CCE of the first common voltage supply area CVA1 may be electrically connected to any one of first pads PD1 of the first pad part PDA1. That is, the plurality of common contact electrode CCE of the first common voltage supply area CVA1 may receive the common voltage supplied from any one of the first pads of the first pad part PDA1.

The plurality of common voltage supply units of the second common voltage supplying area CVA2 may be electrically connected to any one of second pads of the second pad part PDA2. That is, the plurality of common contact electrode CCE of the second common voltage supply area CVA2 may receive the common voltage supplied from any one of the second pads of the second pad part PDA2.

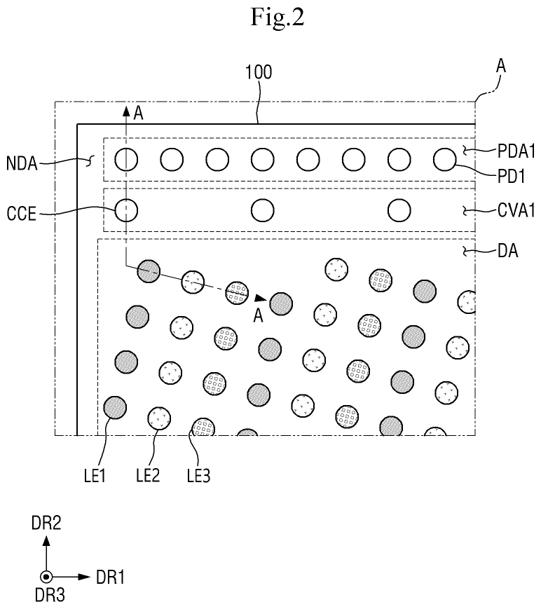

It has been illustrated in FIGS. 1 and 2 that the common voltage supply areas CVA1 and CVA2 are disposed on both sides of the display area DA, but the present disclosure is not limited thereto. For example, the common voltage supply areas CVA1 and CVA2 may also be disposed to surround the display area DA.

The first pad part PDA1 may be disposed on the upper side of the display panel 100. The first pad part PDA1 may include the first pads PD1 connected to an external circuit board.

The second pad part PDA2 may be disposed on the lower side of the display panel 100. The second pad part PDA2 may include the second pads to be connected to the external circuit board. The second pad part PDA2 may be omitted.

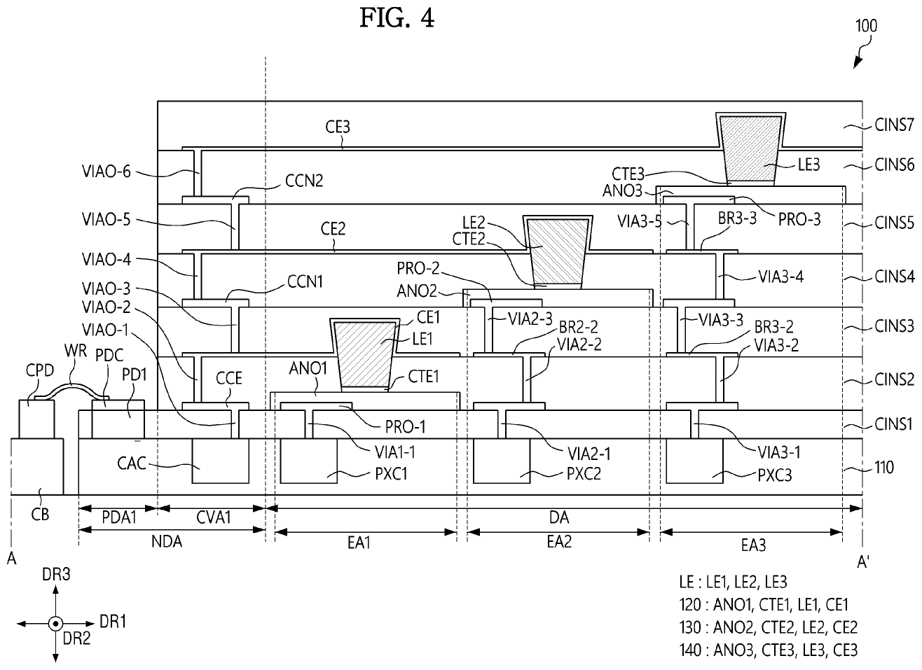

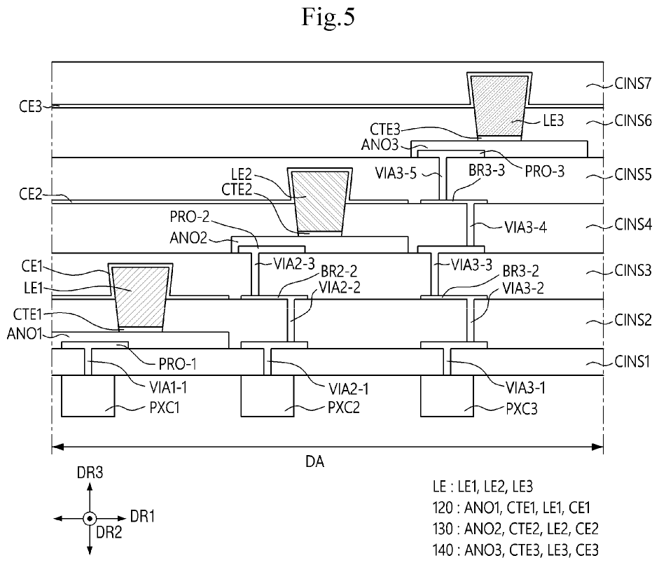

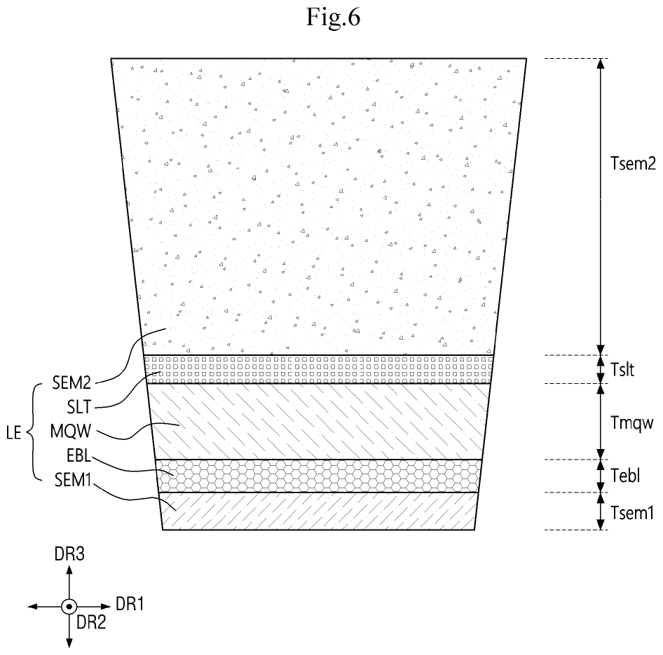

FIG. 4 is a cross-sectional view illustrating an example of the display panel taken along the line A-A′ of FIG. 2. FIG. 5 is an enlarged view of a display panel of a display area of FIG. 4. FIG. 6 is an enlarged view of a light emitting element of FIG. 5.

Referring to FIGS. 4 to 6, the display panel 100 according to one or more embodiments may include a semiconductor circuit substrate 110 and a plurality of light emitting element layers 120, 130, and 140.

The semiconductor circuit substrate 110 may include a plurality of pixel circuit units PXC1, PXC2, and PXC3, first pads PD1, a common contact electrode CCE, and a first insulating layer CINS1.

The semiconductor circuit substrate 110 is a silicon wafer substrate formed using a semiconductor process, and may be a first substrate. The plurality of pixel circuit units PXC1, PXC2, and PXC3 of the semiconductor circuit substrate 110 may be formed using a semiconductor process.

The semiconductor circuit substrate 110 may include the plurality of pixel circuit units PXC1, PXC2, and PXC3.

The plurality of pixel circuit units PXC1, PXC2, and PXC3 may be disposed in the display area DA and the non-display area NDA. Each of the plurality of pixel circuit units PXC1, PXC2, and PXC3 may be connected to each of pixel electrodes ANO1, ANO2, and ANO3 corresponding thereto. The plurality of pixel circuit units PXC1, PXC2, and PXC3 may overlap light emitting elements LE1, LE2, and LE3, respectively, in a third direction DR3 (e.g., a thickness direction of the semiconductor circuit substrate 110).

Each of the plurality of pixel circuit units PXC1, PXC2, and PXC3 may include at least one transistor formed through a semiconductor process. In addition, each of the plurality of pixel circuit units PXC1, PXC2, and PXC3 may further include at least one capacitor formed through a semiconductor process. The plurality of pixel circuit units PXC1, PXC2, and PXC3 may include, for example, complementary metal-oxide semiconductor (CMOS) circuits. The plurality of pixel circuit units PXC1, PXC2, and PXC3 may apply pixel voltages or anode voltages to the pixel electrodes ANO1, ANO2, and ANO3, respectively.

The common contact electrode CCE may be disposed on a common circuit unit CAC corresponding thereto. The common contact electrode CCE may be an exposed electrode exposed from the common circuit unit CAC. The common contact electrode CCE may be formed integrally with the common circuit unit CAC. The common contact electrode CCE may receive a common voltage or a cathode voltage supplied from the common circuit unit CAC. The common contact electrode CCE may include at least one of gold (Au), copper (Cu), aluminum (Al), or tin (Sn).

The common contact electrode CCE may be disposed on the common circuit unit CAC of the non-display area NDA, and may be disposed to surround the display area DA in a plan view. The common contact electrode CCE may be connected to any one of the first pads PD1 of the first pad part PDA1 through the common circuit unit CAC formed in the non-display area NDA to receive the common voltage. The common contact electrode CCE may electrically connect a power line of the common circuit part CAC and common electrodes CE1, CE2, and CE3 of the light emitting element layers 120, 130, and 140 to each other.

A plurality of first pads PD1 may be disposed in the first pad part PDA1 in the non-display area NDA. The plurality of first pads PD1 may be disposed to be spaced from the common contact electrode CCE. The plurality of first pads PD1 may be spaced apart from the common contact electrode CCE toward the outside of the non-display area NDA.

Pad connection electrodes PDC may be disposed on the first pads PD1. The pad connection electrodes PDC may be in contact with upper surfaces of the first pads PD1. The pad connection electrodes PDC may be connected to circuit pads CPD of a circuit board CB through conductive connection members such as wires WR. That is, the first pads PD1, the pad connection electrodes PDC, the wires WR, and the circuit pads CPD of the circuit board CB may be electrically connected to each other.

In one or more embodiments, the semiconductor circuit substrate 110 and the circuit board CB may be disposed on a lower substrate. The semiconductor circuit substrate 110 and the circuit board CB may be attached to an upper surface of the lower substrate using an adhesive member such as a pressure sensitive adhesive.

The circuit board CB may be a flexible printed circuit board (FPCB), a printed circuit board (PCB), a flexible printed circuit (FPC), or a flexible film such as a chip on film (COF).

The first insulating layer CINS1 may be disposed on the semiconductor circuit substrate 110. The first insulating layer CINS1 may be disposed to cover the first pads PD1, the common circuit unit CAC, and the pixel circuit units PXC1, PXC2, and PXC3. In this case, at least partial areas of each of the first pads PD1 and the common circuit unit CAC, and the pixel circuit units PXC1, PXC2, and PXC3 may be exposed without being covered by the first insulating layer CINS1 through contact holes VIA0-1, VIA1-1, VIA2-1, and VIA3-1 penetrating through the first insulating layer CINS1. The first insulating layer CINS1 may be formed as an inorganic film such as a silicon oxide film (SiO₂), an aluminum oxide film (Al₂O₃), or a hafnium oxide film (HfOₓ). The contact holes VIA0-1, VIA1-1, VIA2-1, and VIA3-1 may be filled with the common contact electrode CCE or first protective electrodes PRO-1. An upper surface of the common contact electrode CCE or the first protective electrode PRO-1 may be disposed on an upper surface of the first insulating layer CINS1. The first protective electrodes PRO-1 may serve to protect the pixel circuit units PXC1, PXC2, and PXC3 during a process, and may be formed as a transparent conductive oxide (TCO) single film or composite film having an etching selectivity with respect to a first pixel electrode ANO1.

The plurality of light emitting element layers 120, 130, and 140 may be disposed on the first insulating layer CINS1. The plurality light emitting element layers 120, 130, and 140 may include a first light emitting element layer 120, a second light emitting element layer 130, and a third light emitting element layer 140. Insulating layers CINS3, CINS5, and CIN7 may be disposed between the respective light emitting element layers 120, 130, and 140.

The first light emitting element layer 120 is disposed on the first insulating layer CINS1. The first light emitting element layer 120 may include first pixel electrodes ANO1, first contact electrodes CTE1, first light emitting elements LE1, and a first common electrode CE1.

The first pixel electrode ANO1 may be disposed on the first insulating layer CINS1. The first pixel electrode ANO1 may be disposed to cover the first protective electrode PRO-1. The first pixel electrode ANO1 may be connected to a first pixel circuit unit PXC1 through the first protective electrode PRO-1 and a first connection contact hole VIA1-1 penetrating through the first insulating layer CINS1. The first pixel electrode ANO1 may be formed as a single layer or multiple layers made of one or more of molybdenum (Mo), chromium (Cr), gold (Au), titanium (Ti), nickel (Ni), neodymium (Nd), and/or copper (Cu), and/or alloys thereof. In one or more embodiments, the first pixel electrode ANO1 may be made of a material having reflectivity higher than that of copper (Cu), such as aluminum (Al) and/or silver (Ag).

The first light emitting element LE1 may be disposed on the first pixel electrode ANO1. A first contact electrode CTE1 may be disposed between the first pixel electrode ANO1 and the first light emitting element LE1. The first contact electrodes CTE1 may serve as bonding metals for bonding the first pixel electrodes ANO1 and the first light emitting elements LE1 to each other. For example, the first contact electrodes CTE1 may include at least one of gold (Au), copper (Cu), aluminum (Al), or tin (Sn). Alternatively, the first contact electrodes CTE1 may include a first layer including one or more of gold (Au), copper (Cu), aluminum (Al), and/or tin (Sn) and a second layer including another one or more of gold (Au), copper (Cu), aluminum (Al), and/or tin (Sn). In this case, the second layer may be disposed on the first layer.

In one or more embodiments, the pad connection electrode PDC and the common contact electrode CCE may include the same material as the first contact electrodes CTE1. For example, each of the pad connection electrode PDC and the common contact electrode CCE may include at least one of gold (Au), copper (Cu), aluminum (Al), or tin (Sn). When each of the first contact electrodes CTE1 includes a first layer and a second layer, each of the pad connection electrode PDC and the common contact electrode CCE may include a first layer and a second layer.

The first light emitting element LE1 may be disposed on the first contact electrode CTE1. The first light emitting element LE1 may be a vertical light emitting diode element extending in the third direction DR3. That is, a length of the light emitting element LE in the third direction DR3 may be greater than a length of the light emitting element LE in a horizontal direction. The length in the horizontal direction refers to a length in the first direction DR1 or a length in the second direction DR2. For example, the length of the light emitting element LE in the third direction DR3 may be approximately 1 to 5 μm.

The first light emitting element LE1 may be a micro light emitting diode element or a nano light emitting diode element. The first light emitting element LE1 includes a first semiconductor layer SEM1, an electron blocking layer EBL, an active layer MQW, a superlattice layer SLT, and a second semiconductor layer SEM2 arranged along the third direction DR3, as illustrated in FIG. 6. The first semiconductor layer SEM1, the electron blocking layer EBL, the active layer MQW, the superlattice layer SLT, and the second semiconductor layer SEM2 may be sequentially stacked in the third direction DR3.

The first semiconductor layer SEM1 may be disposed on the first contact electrode CTE1. The first semiconductor layer SEM1 may be doped with a first conductivity-type dopant such as Mg, Zn, Ca, Se, and/or Ba. For example, the first semiconductor layer SEM1 may be made of p-GaN doped with p-type Mg. A thickness Tsem1 of the first semiconductor layer SEM1 may be approximately 30 to 200 nm.

The electron blocking layer EBL may be disposed on the first semiconductor layer SEM1. The electron blocking layer EBL may be a layer for suppressing or preventing too many electrons from flowing to the active layer MQW. For example, the electron blocking layer EBL may be made of p-AlGaN doped with p-type Mg. A thickness Tebl of the electron blocking layer EBL may be approximately 10 to 50 nm. The electron blocking layer EBL may be omitted.

The active layer MQW may be disposed on the electron blocking layer EBL. The active layer MQW may emit light by a combination of electron-hole pairs according to electrical signals applied through the first semiconductor layer SEM1 and the second semiconductor layer SEM2. The active layer MQW may emit first light having a central wavelength band in the range of approximately 600 nm to 750 nm, that is, light of a red wavelength band.

The active layer MQW may include a material having a single or multiple quantum well structure. When the active layer MQW includes the material having the multiple quantum well structure, the active layer MQW may have a structure in which a plurality of well layers and barrier layers are alternately stacked. In this case, the well layer may be made of InGaN, and the barrier layer may be made of GaN an/or AlGaN, but the present disclosure is not limited thereto. A thickness of the well layer may be approximately 1 to 4 nm, and a thickness of the barrier layer may be 3 to 10 nm.

Alternatively, the active layer MQW may have a structure in which semiconductor materials having large band gap energy and semiconductor materials having small band gap energy are alternately stacked, and may include other Group III to Group V semiconductor materials depending on a wavelength band of emitted light.

The superlattice layer SLT may be disposed on the active layer MQW. The superlattice layer SLT may be a layer for alleviating stress between the second semiconductor layer SEM2 and the active layer MQW. For example, the superlattice layer SLT may be made of InGaN or GaN. A thickness Tslt of the superlattice layer SLT may be approximately 50 to 200 nm. The superlattice layer SLT may be omitted.

The second semiconductor layer SEM2 may be disposed on the superlattice layer SLT. The second semiconductor layer SEM2 may be doped with a second conductivity-type dopant such as Si, Ge, and/or Sn. For example, the second semiconductor layer SEM2 may be made of n-GaN doped with n-type Si. A thickness Tsem2 of the second semiconductor layer SEM2 may be approximately 500 nm to 1 μm.

A second insulating layer CINS2 may be disposed on side surfaces of the first light emitting element LE1. The second insulating layer CINS2 may not be disposed on an upper surface of each of the first light emitting elements LE1. In addition, the second insulating layer CINS2 may be disposed on side surfaces of each of the first pixel electrodes ANO1 and the first contact electrodes CTE1. The second insulating layer CINS2 may be disposed to cover the common contact electrode CCE, a protective electrode PRO-1 of a second emission area EA2, and a protective electrode PRO-1 of a third emission area EA3. In this case, at least partial areas of the common contact electrode CCE, the protective electrode PRO-1 of the second emission area EA2, and the protective electrode PRO-1 of the third emission area EA3 may be exposed without being covered by the second insulating layer CINS2 through contact holes VIA0-2, VIA2-2, and VIA3-2 penetrating through the second insulating layer CINS2. The second insulating layer CINS2 may be formed as an inorganic film such as a silicon oxide film (SiO₂), an aluminum oxide film (Al₂O₃), and/or a hafnium oxide film (HfOₓ), but is not limited thereto. The contact holes VIA0-2, VIA2-2 and VIA3-2 may be filled with the first common electrode CE1 or first bridge electrodes BR2-2 and BR3-2. The first bridge electrodes BR2-2 and BR3-2 are made of the same material as the first common electrode CE1. The first bridge electrodes BR2-2 and BR3-2 are disposed to be spaced from the first common electrode CE1.

The first common electrode CE1 is connected to the common contact electrode CCE through the contact hole VIA0-2 in the first common voltage supply area CVA1. The first bridge electrode BR2-2 of the second emission area EA2 is connected to the pixel circuit unit PXC2 through the contact hole VIA2-2 and the protective electrode PRO-1. The first bridge electrode BR3-2 of the third emission area EA3 is connected to the pixel circuit unit PXC3 through the contact hole VIA3-2 and the protective electrode PRO-1.

The first common electrode CE1 may be disposed on the upper surface of each of the first light emitting elements LE1 and an upper surface of the second insulating layer CINS2. The first common electrode CE1 may be disposed to completely cover each of the first light emitting elements LE1.

The first common electrode CE1 may include a transparent conductive material. For example, the first common electrode CE1 may include a transparent conductive oxide (TCO) such as indium tin oxide (ITO) and/or indium zinc oxide (IZO).

A third insulating layer CINS3 may be disposed on the first light emitting element layer 120. The third insulating layer CINS3 may be disposed to cover the first common electrode CE1 and the first bridge electrodes BR2-2 and BR3-2. In this case, at least partial areas of each of the first bridge electrodes BR2-2 and BR3-2 of the second and third emission areas EA2 and EA3 and the first common electrode CE1 of the first common voltage supply area CVA1 may be exposed without being covered by the third insulating layer CINS3 through contact holes VIA0-3, VIA2-3, and VIA3-3 penetrating through the third insulating layer CINS3. The third insulating layer CINS3 may be formed as an inorganic film such as a silicon oxide film (SiO₂), an aluminum oxide film (Al₂O₃), and/or a hafnium oxide film (HfOₓ). The contact holes VIA0-3, VIA2-3, and VIA3-3 may be filled with a first common connection electrode CCN1 or second protective electrodes PRO-2. Upper surfaces of the first common connection electrode CCN1 and the second protective electrodes PRO-2 may be disposed on an upper surface of the third insulating layer CINS3.

The second light emitting element layer 130 is disposed on the third insulating layer CINS3. The second light emitting element layer 130 may include second pixel electrodes ANO2, second contact electrodes CTE2, second light emitting elements LE2, and a second common electrode CE2.

The first pixel electrode ANO1 may be disposed on the first insulating layer CINS1. The first pixel electrode ANO1 may be disposed to cover the first protective electrode PRO-1. The first pixel electrode ANO1 may be connected to a first pixel circuit unit PXC1 through the first protective electrode PRO-1 and a first connection contact hole VIA1-1 penetrating through the first insulating layer CINS1. The first pixel electrode ANO1 may be formed as a single layer or multiple layers made of one or more of molybdenum (Mo), chromium (Cr), gold (Au), titanium (Ti), nickel (Ni), neodymium (Nd), and/or copper (Cu), and/or alloys thereof. In one or more embodiments, the first pixel electrode ANO1 may be made of a material having reflectivity higher than that of copper (Cu), such as aluminum (Al), and/or silver (Ag). The first light emitting element LE1 may be disposed on the first pixel electrode ANO1.

The second pixel electrode ANO2 may be disposed on the third insulating layer CINS3 of the second emission area EA2. The second pixel electrode ANO2 may be disposed to cover the second protective electrode PRO-2. The second pixel electrode ANO2 may be connected to a second pixel circuit unit PXC2 through the second protective electrode PRO-2, the first bridge electrode BR2-2, and the first protective electrode PRO-1. The second pixel electrode ANO2 may be formed as a single layer or multiple layers made of one or more of molybdenum (Mo), chromium (Cr), gold (Au), titanium (Ti), nickel (Ni), neodymium (Nd), and/or copper (Cu), and/or alloys thereof. In one or more embodiments, the second pixel electrode ANO2 may be made of a material having reflectivity higher than that of copper (Cu), such as aluminum (Al) and/or silver (Ag).

The second light emitting element LE2 may be disposed on the second pixel electrode ANO2. A second contact electrode CTE2 may be disposed between the second pixel electrode ANO2 and the second light emitting element LE2. The second contact electrodes CTE2 may serve as bonding metals for bonding the second pixel electrodes ANO2 and the second light emitting elements LE2 to each other. For example, the second contact electrodes CTE2 may include at least one of gold (Au), copper (Cu), aluminum (Al), or tin (Sn). Alternatively, the second contact electrodes CTE2 may include a first layer including one or more of gold (Au), copper (Cu), aluminum (Al), and/or tin (Sn) and/or a second layer including another one or more of gold (Au), copper (Cu), aluminum (Al), and/or tin (Sn). In this case, the second layer may be disposed on the first layer.

The second light emitting element LE2 may be disposed on the second contact electrode CTE2. The second light emitting element LE2 may be a vertical light emitting diode element extending in the third direction DR3, similar to the first light emitting element LE1. The second light emitting element LE2 includes a first semiconductor layer SEM1, an electron blocking layer EBL, an active layer MQW, a superlattice layer SLT, and a second semiconductor layer SEM2 arranged along the third direction DR3, similar to the first light emitting element LE1. The first semiconductor layer SEM1, the electron blocking layer EBL, the active layer MQW, the superlattice layer SLT, and the second semiconductor layer SEM2 may be sequentially stacked along the third direction DR3. The first semiconductor layer SEM1, the electron blocking layer EBL, the active layer MQW, the superlattice layer SLT, and the second semiconductor layer SEM2 are similar to the first semiconductor layer SEM1, the electron blocking layer EBL, the active layer MQW, the superlattice layer SLT, and the second semiconductor layer SEM2 of the first light emitting element LE1, respectively, and a detailed description thereof will thus be omitted. However, the active layer MQW of the second light emitting element LE2 is different from the active layer MQW of the first light emitting element LE1 in that it emits second light having a central wavelength band in the range of approximately 480 nm to 560 nm, that is, light of a green wavelength band.

A fourth insulating layer CINS4 may be disposed on side surfaces of the second light emitting element LE2. The fourth insulating layer CINS4 may not be disposed on an upper surface of each of the second light emitting elements LE2. In addition, the fourth insulating layer CINS4 may be disposed on side surfaces of each of the second pixel electrodes ANO2 and the second contact electrodes CTE2. The fourth insulating layer CINS4 may be disposed to cover the second protective electrode PRO-2 of the third emission area EA3. In this case, at least partial areas of the second protective electrode PRO-2 and the first common connection electrode CCN1 may be exposed without being covered by the fourth insulating layer CINS4 through contact holes VIA0-4 and VIA3-4 penetrating through the fourth insulating layer CINS4. The fourth insulating layer CINS4 may be formed as an inorganic film such as a silicon oxide film (SiO₂), an aluminum oxide film (Al₂O₃), and/or a hafnium oxide film (HfOₓ), but is not limited thereto. The contact holes VIA0-4 and VIA3-4 may be filled with the second common electrode CE2 or a second bridge electrode BR3-3. The second bridge electrode BR3-3 is made of the same material as the second common electrode CE2. The second bridge electrode BR3-3 is disposed to be spaced from the second common electrode CE2.

The second common electrode CE2 is connected to the common contact electrode CCE through the contact holes VIA0-2, VIA0-3, and VIA0-4 via the first common connection electrode CCN1 and the first common electrode CE1 in the first common voltage supply area CVA1. The second bridge electrode BR3-3 of the third emission area EA3 is connected to the pixel circuit unit PXC3 through the first bridge electrode BR3-2 and the protective electrodes PRO-1 and PRO-2.

The second common electrode CE2 may be disposed on the upper surface of each of the second light emitting elements LE2 and an upper surface of the fourth insulating layer CINS4. The second common electrode CE2 may be disposed to completely cover each of the second light emitting elements LE2.

The second common electrode CE2 may include a transparent conductive material. For example, the second common electrode CE2 may include a transparent conductive oxide (TCO) such as indium tin oxide (ITO) and/or indium zinc oxide (IZO).

A fifth insulating layer CINS5 may be disposed on the second light emitting element layer 130. The fifth insulating layer CINS5 may be disposed to cover the second common electrode CE2 and the second bridge electrode BR3-3. In this case, at least partial areas of each of the second bridge electrode BR3-3 of the third emission area EA3 and the second common electrode CE2 of the first common voltage supply area CVA1 may be exposed without being covered by the fifth insulating layer CINS5 through contact holes VIA0-5 and VIA3-5 penetrating through the fifth insulating layer CINS5. The fifth insulating layer CINS5 may be formed as an inorganic film such as a silicon oxide film (SiO₂), an aluminum oxide film (Al₂O₃), and/or a hafnium oxide film (HfOₓ). The contact holes VIA0-5 and VIA3-5 may be filled with a second common connection electrode CCN2 or a third protective electrode PRO-3. Upper surfaces of the second common connection electrode CCN2 and the third protective electrode PRO-3 may be disposed on an upper surface of the fifth insulating layer CINS5.

A third pixel electrode ANO3 may be disposed on the fifth insulating layer CINS5 of the third emission area EA3. The third pixel electrode ANO3 may be disposed to cover the third protective electrode PRO-3. The third pixel electrode ANO3 may be connected to a third pixel circuit unit PXC3 through the third protective electrode PRO-3, the second bridge electrode BR3-3, the second protective electrode PRO-2, the first bridge electrode BR3-2, and the first protective electrode PRO-1. The third pixel electrode ANO3 may be formed as a single layer or multiple layers made of one or more of molybdenum (Mo), chromium (Cr), gold (Au), titanium (Ti), nickel (Ni), neodymium (Nd), and/or copper (Cu), and/or alloys thereof. In one or more embodiments, the third pixel electrode ANO3 may be made of a material having reflectivity higher than that of copper (Cu), such as aluminum (Al) and/or silver (Ag).

A third light emitting element LE3 may be disposed on the third pixel electrode ANO3. A third contact electrode CTE3 may be disposed between the third pixel electrode ANO3 and the third light emitting element LE3. The third contact electrodes CTE3 may serve as bonding metals for bonding the third pixel electrodes ANO3 and the third light emitting elements LE3. For example, the third contact electrodes CTE3 may include at least one of gold (Au), copper (Cu), aluminum (Al), or tin (Sn). Alternatively, the third contact electrodes CTE3 may include a first layer including one or more of gold (Au), copper (Cu), aluminum (Al), and/or tin (Sn) and a second layer including another one or more of gold (Au), copper (Cu), aluminum (Al), and/or tin (Sn). In this case, the second layer may be disposed on the first layer.

The third light emitting element LE3 may be disposed on the third contact electrode CTE3. The third light emitting element LE3 may be a vertical light emitting diode element extending in the third direction DR3, similar to the first light emitting element LE1. The third light emitting element LE3 includes a first semiconductor layer SEM1, an electron blocking layer EBL, an active layer MQW, a superlattice layer SLT, and a second semiconductor layer SEM2 arranged along the third direction DR3, similar to the first light emitting element LE1. The first semiconductor layer SEM1, the electron blocking layer EBL, the active layer MQW, the superlattice layer SLT, and the second semiconductor layer SEM2 may be sequentially stacked in the third direction DR3. The first semiconductor layer SEM1, the electron blocking layer EBL, the active layer MQW, the superlattice layer SLT, and the second semiconductor layer SEM2 are similar to the first semiconductor layer SEM1, the electron blocking layer EBL, the active layer MQW, the superlattice layer SLT, and the second semiconductor layer SEM2 of the first light emitting element LE1, respectively, and a detailed description thereof will thus be omitted. However, the active layer MQW of the third light emitting element LE3 is different from the active layer MQW of the first light emitting element LE1 in that it emits third light having a central wavelength band in the range of approximately 370 nm to 460 nm, that is, light of a blue wavelength band.

The third light emitting element LE3 is connected to the pixel circuit unit PXC3 through the third pixel electrode ANO3.

A sixth insulating layer CINS6 may be disposed on side surfaces of the third light emitting element LE3. The sixth insulating layer CINS6 may not be disposed on an upper surface of each of the third light emitting elements LE3. In addition, the sixth insulating layer CINS6 may be disposed on side surfaces of each of the third pixel electrodes ANO3 and the third contact electrodes CTE3. The sixth insulating layer CINS6 may be disposed to cover the second common connection electrode CCN2 in the first common voltage supply area CVA1. In this case, at least a partial area of the second common connection electrode CCN2 may be exposed without being covered by the sixth insulating layer CINS6 through a contact hole VIA0-6 penetrating through the sixth insulating layer CINS6. The sixth insulating layer CINS6 may be formed as an inorganic film such as a silicon oxide film (SiO₂), an aluminum oxide film (Al₂O₃), and/or a hafnium oxide film (HfOₓ), but is not limited thereto. The contact hole VIA0-6 may be filled with a third common electrode CE3.

The third common electrode CE3 may be disposed on the upper surface of each of the third light emitting elements LE3 and an upper surface of the sixth insulating layer CINS6. The third common electrode CE3 may be disposed to completely cover each of the third light emitting elements LE3.

The third common electrode CE3 may include a transparent conductive material. For example, the third common electrode CE3 may include a transparent conductive oxide (TCO) such as indium tin oxide (ITO) and/or indium zinc oxide (IZO).

A seventh insulating layer CINS7 may be disposed on the third light emitting element layer 140. The seventh insulating layer CINS7 may be disposed to cover the third common electrode CE3. The seventh insulating layer CINS7 may be formed as an inorganic film such as a silicon oxide film (SiO₂), an aluminum oxide film (Al₂O₃), and/or a hafnium oxide film (HfOₓ).

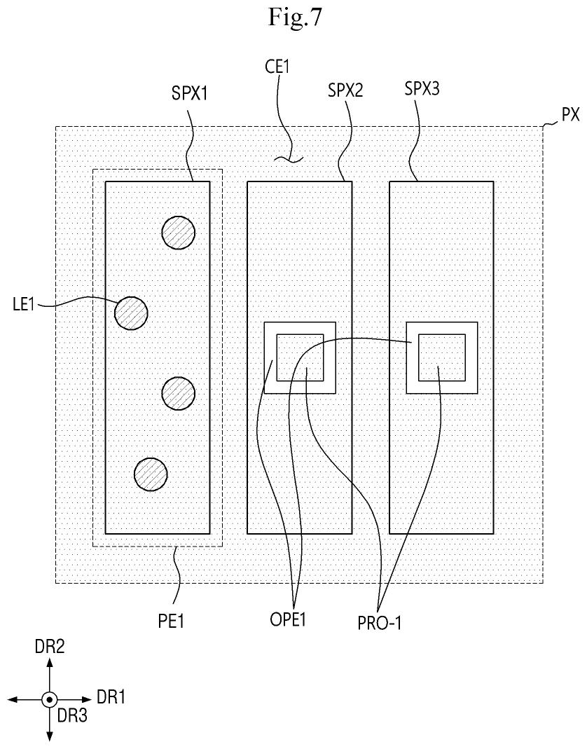

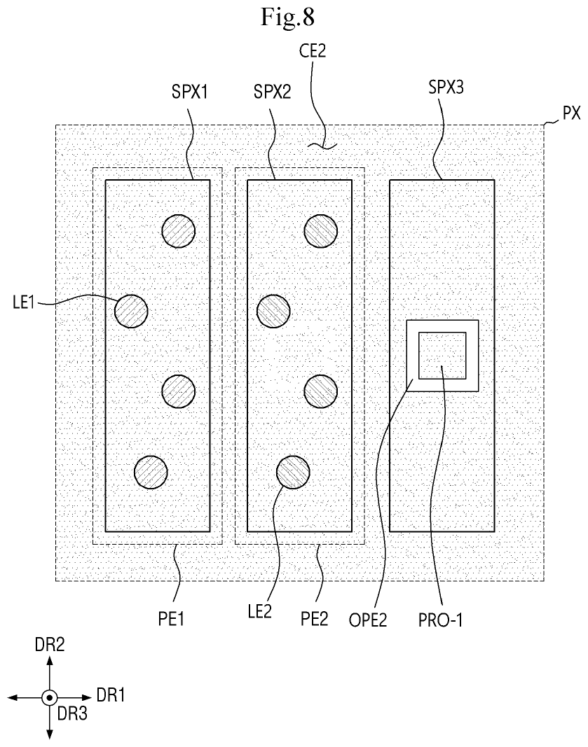

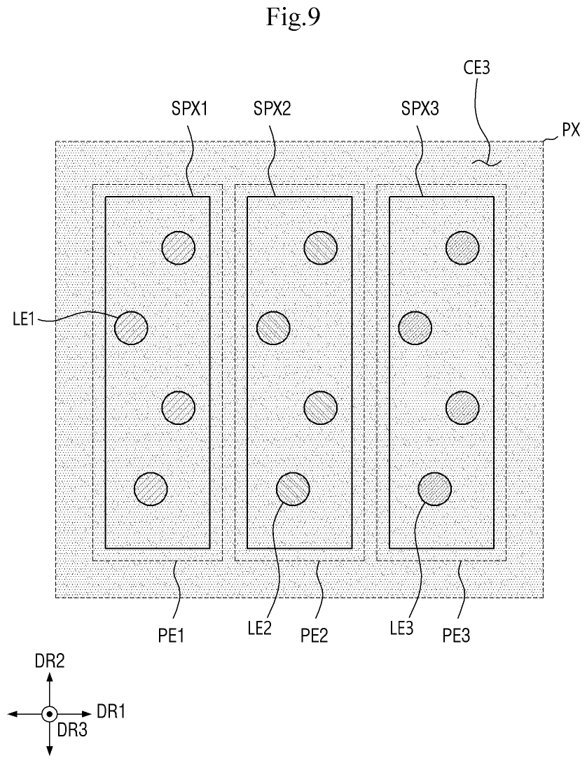

FIG. 7 is a plan view of a first light emitting element layer according to one or more embodiments of the present disclosure, FIG. 8 is a plan view of first and second light emitting element layers according to one or more embodiments of the present disclosure, and FIG. 9 is a plan view of first to third light emitting element layers according to one or more embodiments of the present disclosure.

Referring to FIG. 7, the first common electrode CE1 may cover all of the first to third sub-pixels SPX1 to SPX3. In this case, the first common electrode CE1 may have first openings OPE1 surrounding the first protective electrodes PRO-1 of the second sub-pixel SPX2 and the third sub-pixel SPX3.

Referring to FIG. 8, the second common electrode CE2 may cover all of the first to third sub-pixels SPX1 to SPX3. In this case, the second common electrode CE2 may have a second opening OPE2 surrounding the first protective electrode PRO-1 of the third sub-pixel SPX3.

Referring to FIG. 9, the third common electrode CE3 may cover all of the first to third sub-pixels SPX1 to SPX3.

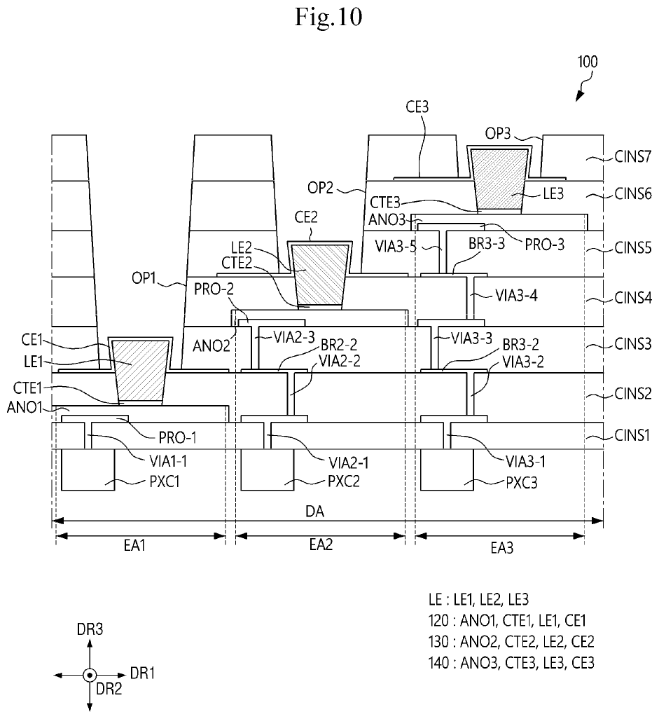

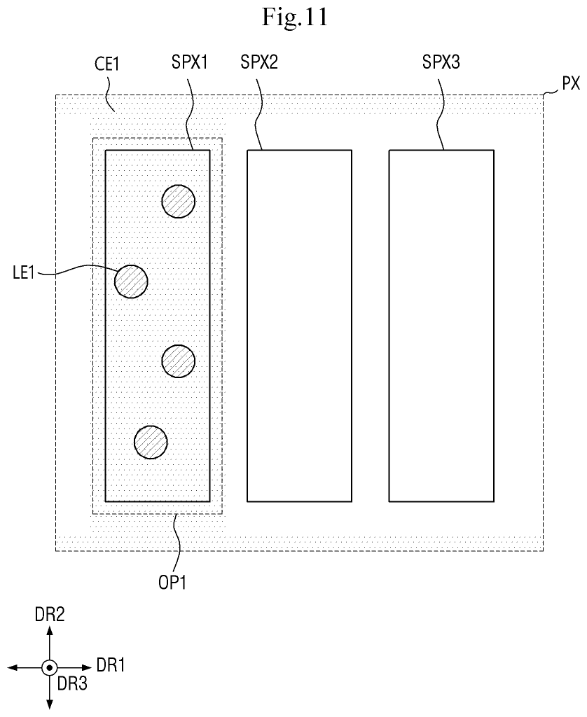

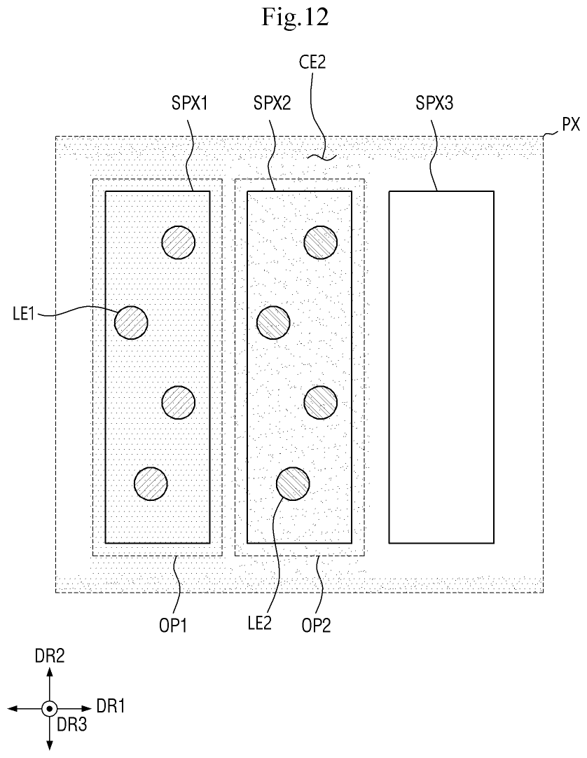

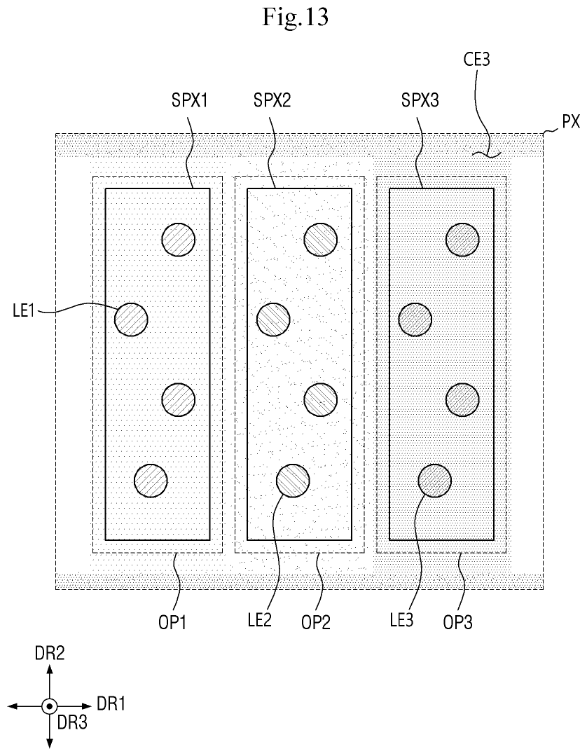

FIG. 10 is an enlarged view of the display panel of the display area of FIG. 4 according to one or more embodiments, FIG. 11 is a plan view of a first light emitting element layer of FIG. 10, FIG. 12 is a plan view of first and second light emitting element layers of FIG. 10, and FIG. 13 is a plan view of first to third light emitting element layers of FIG. 10.

Referring to FIG. 10, a display panel 100 is different from the display panel 100 according to an embodiment described above with reference to FIGS. 4 and 5 in that the insulating layers CINS3, CINS4, CINS5, CINS6, and CINS7 on the light emitting elements LE1, LE2, and LE3 are removed. Hereinafter, a description of the same configuration will be simplified or omitted, and configurations different from those described above will be described in detail.

Referring to FIGS. 10 and 11, the first common electrode CE1 of the first light emitting element LE1 may be formed to bypass the second emission area EA2 and the third emission area EA3. In addition, the insulating layers CINS3, CINS4, CINS5, CINS6, and CINS7 of the first emission area EA1 may be removed. An opening OP1 may be formed in the insulating layers CINS3, CINS4, CINS5, CINS6, and CINS7 of the first emission area EA1. A width of the opening OP1 may be greater than that of the light emitting element.

Referring to FIGS. 10 and 12, the second common electrode CE2 of the second light emitting element LE2 may be formed to bypass the first emission area EA1 and the third emission area EA3. In addition, the insulating layers CINS5, CINS6, and CINS7 of the second emission area EA2 may be removed. An opening OP2 may be formed in the insulating layers CINS5, CINS6, and CINS7 of the second emission area EA2.

Referring to FIGS. 10 and 13, the third common electrode CE3 of the third light emitting element LE3 may be formed to bypass the first emission area EA1 and the second emission area EA2. In addition, the insulating layer CINS7 of the third emission area EA3 may be removed. An opening OP3 may be formed in the insulating layer CINS7 of the third emission area EA3.

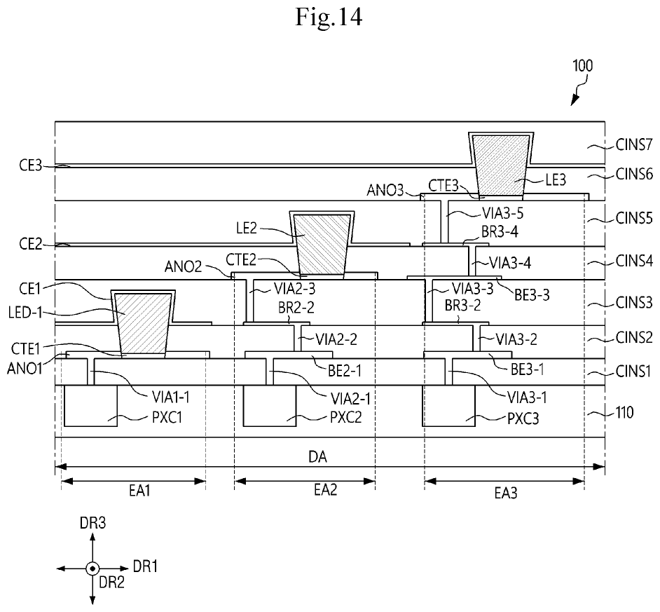

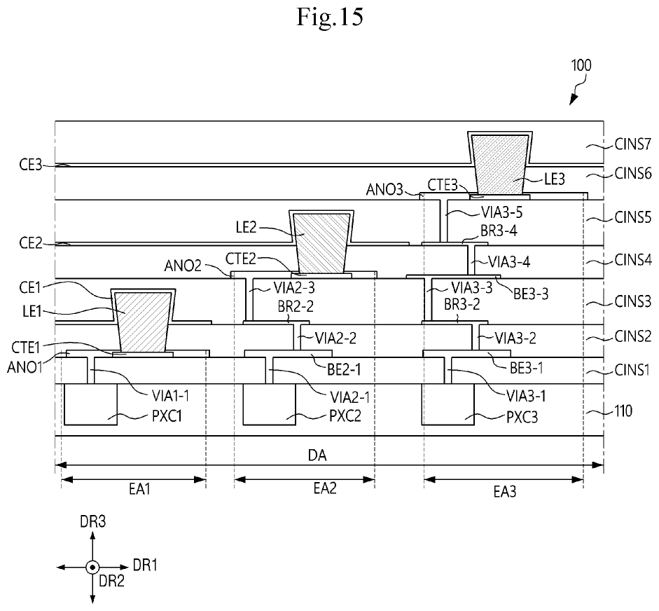

FIG. 14 is an enlarged view of the display panel of the display area of FIG. 4 according to one or more embodiments. FIG. 15 is an enlarged view of the display panel of the display area of FIG. 4 according to one or more embodiments.

Referring to FIGS. 14 and 15, a display panel 100 according to the present embodiment is different from the display panel 100 according to an embodiment described above with reference to FIGS. 4 and 5 in that the contact electrodes CTE1, CTE2, and CTE3 of the light emitting elements LE1, LE2, and LE3 are in side-contact with the pixel electrodes ANO1, ANO2, and ANO3, respectively, and the pixel electrodes ANO1, ANO2, and ANO3 are formed to fill the contact holes VIA1-1, VIA2-3, and VIA3-5, respectively, without the protective electrodes. Hereinafter, a description of the same configuration will be simplified or omitted, and configurations different from those described above will be described in detail.

The first light emitting element LE1 is disposed on the first insulating layer CINS1. The first contact electrode CTE1 may be disposed between the first insulating layer CINS1 and the first light emitting element LE1. The first contact electrode CTE1 may be disposed on the first insulating layer CINS1. In addition, side surfaces of the first contact electrode CTE1 are in contact with the first pixel electrode ANO1.

As illustrated in FIG. 15, the first contact electrode CTE1 may be formed to protrude outward of the first light emitting element LE1. In this case, the first pixel electrode ANO1 may be formed to cover a protrusion area of the first contact electrode CTE1. Accordingly, a wider contact area between the first pixel electrode ANO1 and the first contact electrode CTE1 may be secured.

The first insulating layer CINS1 may include contact holes VIA1-1, VIA2-1, and VIA3-1 penetrating through the first insulating layer CINS1. The contact holes VIA1-1, VIA2-1, and VIA3-1 may be filled with the first pixel electrode ANO1 and first connection electrodes BE2-1 and BE3-1, respectively. The first connection electrodes BE2-1 and BE3-1 may be made of the same material as the first pixel electrode ANO1. Upper surfaces of the first pixel electrode ANO1 and the first connection electrodes BE2-1 and BE3-1 may be disposed on an upper surface of the first insulating layer CINS1.

The second light emitting element LE2 is disposed on the third insulating layer CINS3. The second contact electrode CTE2 may be disposed between the third insulating layer CINS3 and the second light emitting element LE2. The second contact electrode CTE2 may be disposed on the third insulating layer CINS3. In addition, side surfaces of the second contact electrode CTE2 are in contact with the second pixel electrode ANO2.

As illustrated in FIG. 15, the second contact electrode CTE2 may be formed to protrude outward of the second light emitting element LE2. In this case, the second pixel electrode ANO2 may be formed to cover a protrusion area of the second contact electrode CTE2. Accordingly, a wider contact area between the second pixel electrode ANO2 and the second contact electrode CTE2 may be secured.

The third insulating layer CINS3 may include contact holes VIA2-3 and VIA3-3 penetrating through the third insulating layer CINS3. The contact holes VIA2-3 and VIA3-3 may be filled with the second pixel electrode ANO2 and a second connection electrode BE3-3, respectively. The second connection electrode BE3-3 may be made of the same material as the second pixel electrode ANO2. Upper surfaces of the second pixel electrode ANO2 and the second connection electrode BE3-3 may be disposed on an upper surface of the third insulating layer CINS3.

The third light emitting element LE3 is disposed on the fifth insulating layer CINS5. The third contact electrode CTE3 may be disposed between the fifth insulating layer CINS5 and the third light emitting element LE3. The third contact electrode CTE3 may be disposed on the fifth insulating layer CINS5. In addition, side surfaces of the third contact electrode CTE3 are in contact with the third pixel electrode ANO3.

As illustrated in FIG. 15, the third contact electrode CTE3 may be formed to protrude outward of the third light emitting element LE3. In this case, the third pixel electrode ANO3 may be formed to cover a protrusion area of the third contact electrode CTE3. Accordingly, a wider contact area between the third pixel electrode ANO3 and the third contact electrode CTE3 may be secured.

The fifth insulating layer CINS5 may include a contact hole VIA3-5 penetrating through the fifth insulating layer CINS5. The contact hole VIA3-5 may be filled with the third pixel electrode ANO3. An upper surface of the third pixel electrode ANO3 may be disposed on an upper surface of the fifth insulating layer CINS5.

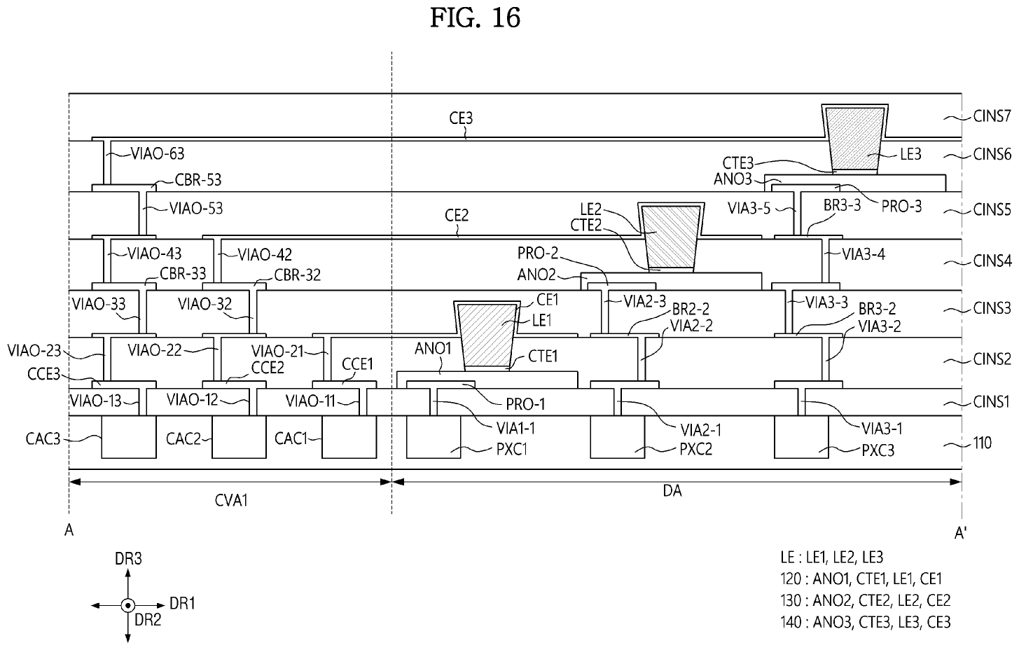

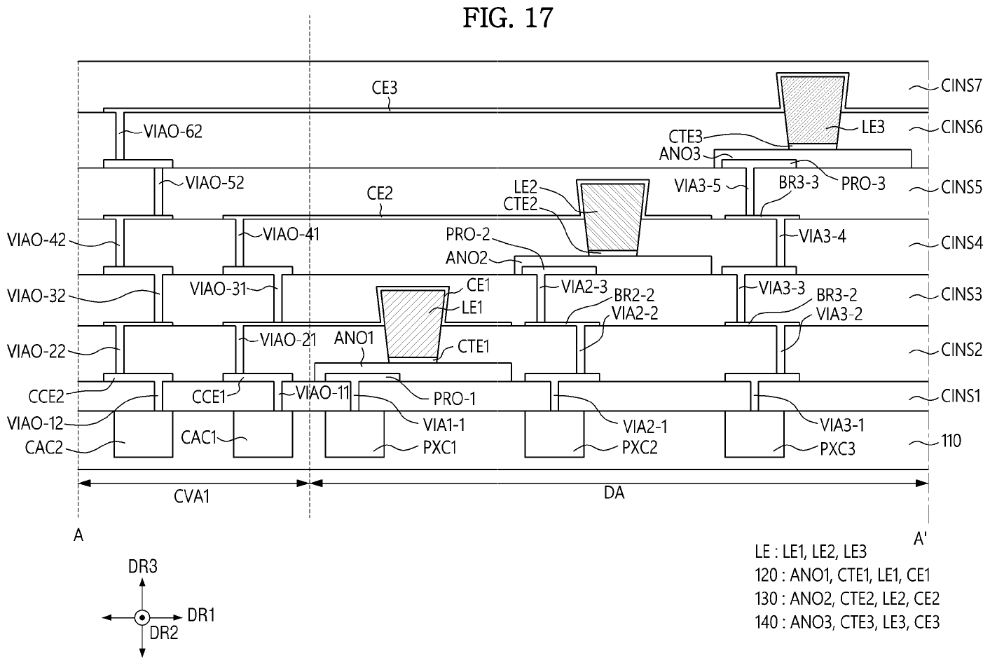

FIG. 16 is a cross-sectional view illustrating an example of a display panel taken along the line A-A′ of FIG. 2 according to one or more embodiments of the present disclosure, and FIG. 17 is a cross-sectional view illustrating an example of a display panel taken along the line A-A′ of FIG. 2 according to one or more embodiments of the present disclosure.

Referring to FIG. 16, a display panel 100 according to the present embodiment is different from the display panel 100 according to an embodiment described above with reference to FIGS. 4 and 5 in that the first common electrode CE1, the second common electrode CE2, and the third common electrode CE3 are separated from each other and are in contact with separate common circuit units CAC in the first common voltage supply area CVA1. Hereinafter, a description of the same configuration will be simplified or omitted, and configurations different from those described above will be described in detail.

A first common circuit unit CAC1, a second common circuit unit CAC2, and a third common circuit unit CAC3 may be included in the first common voltage supply area CVA1.

The first insulating layer CINS1 may be disposed on the semiconductor circuit substrate 110. The first insulating layer CINS1 may be disposed to cover the first common circuit unit CAC1, the second common circuit unit CAC2, and the third common circuit unit CAC3. In this case, at least partial areas of each of the first common circuit unit CAC1, the second common circuit unit CAC2, and the third common circuit unit CAC3 may be exposed without being covered by the first insulating layer CINS1 through contact holes VIA0-11, VIA0-12, and VIA0-13 penetrating through the first insulating layer CINS1.

A first common contact electrode CCE1, a second common contact electrode CCE2, and a third common contact electrode CCE3 may be exposed electrodes exposed from the common circuit units CAC. The first common contact electrode CCE1, the second common contact electrode CCE2, and the third common contact electrode CCE3 may receive common voltages or cathode voltages supplied from the common circuit units CAC. The first common contact electrode CCE1, the second common contact electrode CCE2, and the third common contact electrode CCE3 may include at least one of gold (Au), copper (Cu), aluminum (Al), or tin (Sn).

The first common contact electrode CCE1, the second common contact electrode CCE2, and the third common contact electrode CCE3 may be disposed on the common circuit units CAC of the non-display area NDA, and may be disposed to surround the display area DA in a plan view.

The first common contact electrode CCE1 is connected to the first common electrode CE1 of the first light emitting element LE1 through a through hole VIA0-21 of the second insulating layer CINS2.

The second common contact electrode CCE2 is connected to the second common electrode CE2 of the second light emitting element LE2 through a through hole VIA0-22 of the second insulating layer CINS2, a through hole VIA0-32 of the third insulating layer CINS3, and a through hole VIA0-42 of the fourth insulating layer CINS4.

The third common contact electrode CCE3 is connected to the third common electrode CE3 of the third light emitting element LE3 through a through hole VIA0-23 of the second insulating layer CINS2, a through hole VIA0-33 of the third insulating layer CINS3, a through hole VIA0-43 of the fourth insulating layer CINS4, a through hole VIA0-53 of the fifth insulating layer CINS5, and a through hole VIA0-63 of the sixth insulating layer CINS6.

Referring to FIG. 17, a display panel 100 according to the present embodiment is different from the display panel 100 according to an embodiment described above with reference to FIGS. 4 and 5 in that some of the first common electrode CE1, the second common electrode CE2, and the third common electrode CE3 are partially separated from and partially integrated with each other and are in contact with separate common circuit units CAC in the first common voltage supply area CVA1. Hereinafter, a description of the same configuration will be simplified or omitted, and configurations different from those described above will be described in detail.

A first common circuit unit CAC1 and a second common circuit unit CAC2 may be included in the first common voltage supply area CVA1.

The first insulating layer CINS1 may be disposed on the semiconductor circuit substrate 110. The first insulating layer CINS1 may be disposed to cover the first common circuit unit CAC1 and the second common circuit unit CAC2. In this case, at least partial areas of each of the first common circuit unit CAC1 and the second common circuit unit CAC2 may be exposed without being covered by the first insulating layer CINS1 through contact holes VIA0-11 and VIA0-12 penetrating through the first insulating layer CINS1.

A first common contact electrode CCE1 and a second common contact electrode CCE2 may be exposed electrodes exposed from the common circuit units CAC. The first common contact electrode CCE1 and the second common contact electrode CCE2 may receive common voltages or cathode voltages supplied from the common circuit units CAC1 and CAC2. The first common contact electrode CCE1 and the second common contact electrode CCE2 may include at least one of gold (Au), copper (Cu), aluminum (Al), or tin (Sn).

The first common contact electrode CCE1 and the second common contact electrode CCE2 may be disposed on the common circuit units CAC1 and CAC2 of the non-display area NDA, respectively, and may be disposed to surround the display area DA in a plan view.

In addition, the first common contact electrode CCE1 is connected to the first common electrode CE1 of the first light emitting element LE1 through a through hole VIA0-21 of the second insulating layer CINS2.

The common contact electrode CCE1 is connected to the second common electrode CE2 of the second light emitting element LE2 through the through hole VIA0-21 of the second insulating layer CINS2, the first common electrode CE1, a through hole VIA0-31 of the third insulating layer CINS3, the second protective electrode PRO-2, and a through hole VIA0-41 of the fourth insulating layer CINS4. That is, the first common contact electrode CCE1 may receive the common voltage or the cathode voltage supplied from the common circuit unit CAC1 and transmit the common voltage or the cathode voltage to the first common electrode CE1 and the second common electrode CE2.

The second common contact electrode CCE2 is connected to the third common electrode CE3 of the third light emitting element LE3 through a through hole VIA0-22 of the second insulating layer CINS2, a through hole VIA0-32 of the third insulating layer CINS3, the second protective electrodes PRO-2, a through hole VIA0-42 of the fourth insulating layer CINS4, a through hole VIA0-52 of the fifth insulating layer CINS5, the third protective electrodes PRO-3, and a through hole VIA0-62 of the sixth insulating layer CINS6.

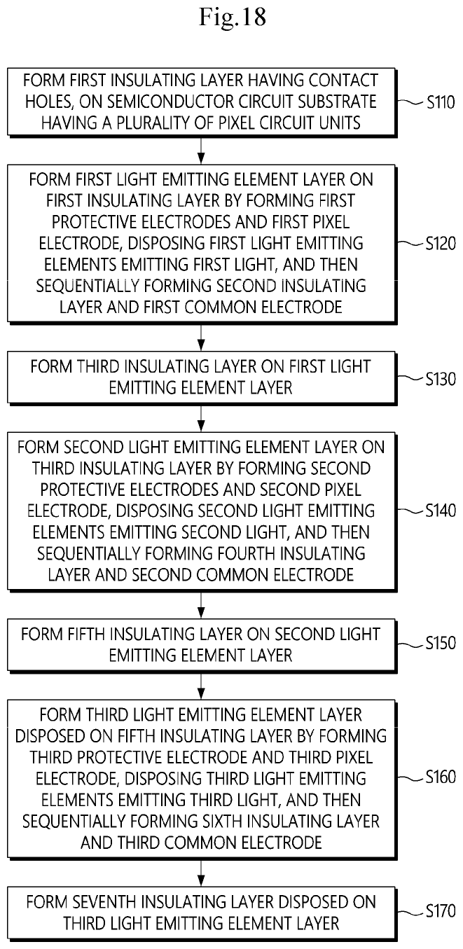

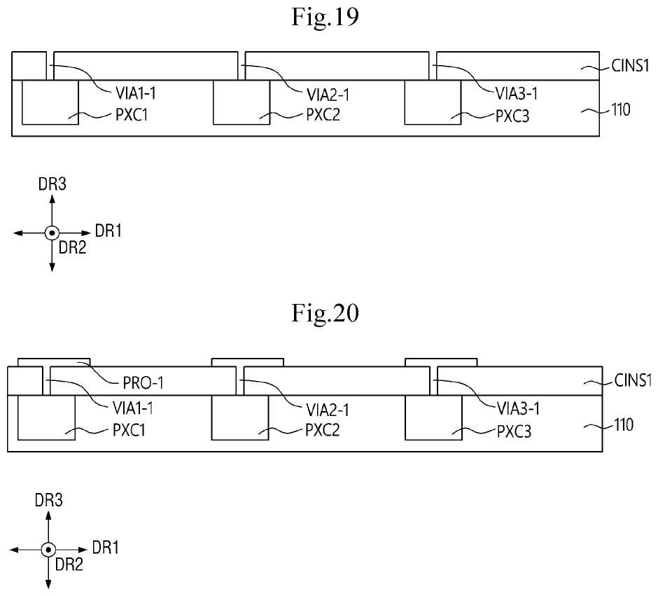

FIG. 18 is a flowchart illustrating a method of fabricating a display device according to one or more embodiments of the present disclosure, and FIGS. 19 to 45 are cross-sectional views for describing the method of fabricating a display device according to one or more embodiments.

Hereinafter, a method of fabricating a display panel according to one or more embodiments will be described in detail with reference to FIGS. 19 to 45.

First, the first insulating layer CINS1 having the contact holes VIA1-1, VIA2-1, and VIA3-1 is formed on the semiconductor circuit substrate 110 (S110 of FIG. 18).

Specifically, referring to FIG. 19, the first insulating layer CINS1 is formed by applying a first insulating material onto the semiconductor circuit substrate 110, and the contact holes VIA1-1, VIA2-1, and VIA3-1 are formed by etching suitable areas (e.g., predetermined areas) on the first insulating layer CINS1 through a photo & dry etch process. The plurality of pixel circuit units PXC1, PXC2, and PXC3 may be exposed through the contact holes VIA1-1, VIA2-1, and VIA3-1. The first insulating material may be an inorganic film such as a silicon oxide film (SiO₂), an aluminum oxide film (Al₂O₃), or a hafnium oxide film (HfOₓ).

Next, the protective electrodes PRO-1 and the first light emitting element layer 120 are formed on the first insulating layer CINS1 (S120 of FIG. 18).

Specifically, as illustrated in FIG. 20, the protective electrodes PRO-1 are formed by covering the first insulating layer CINS1 with a protective electrode material and patterning the protective electrode material. The protective electrode material may fill the contact holes VIA1-1, VIA2-1, and VIA3-1. The protective electrodes PRO-1 may be formed on the contact holes VIA1-1, VIA2-1, and VIA3-1. Accordingly, the protective electrodes PRO-1 are connected to the plurality of pixel circuit units PXC1, PXC2, and PXC3 through the contact holes VIA1-1, VIA2-1, and VIA3-1. The protective electrode material may be a transparent conductive oxide (TCO) having an etching selectivity with respect to the first pixel electrode ANO1.

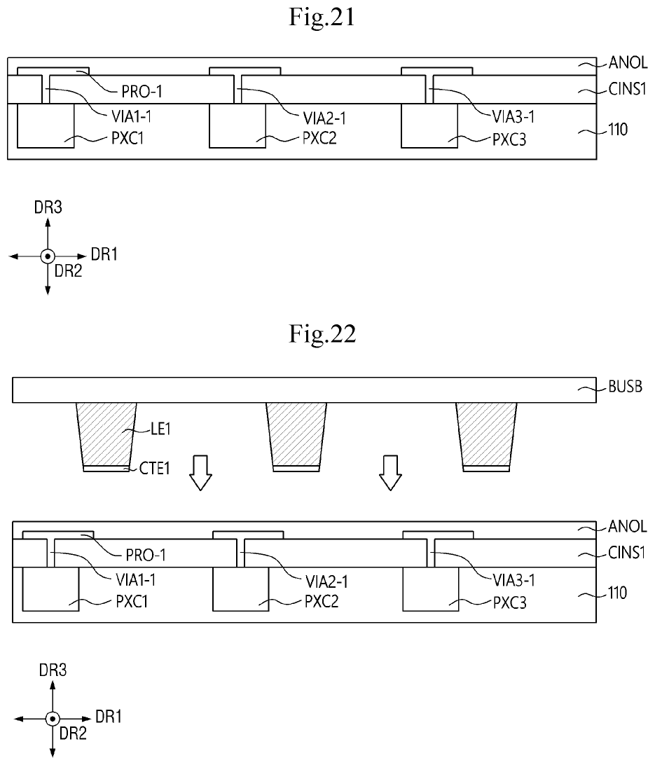

As illustrated in FIG. 21, a pixel electrode layer ANOL is formed by covering the first insulating layer CINS1 on which the protective electrodes PRO-1 are formed, with a pixel electrode material. The pixel electrode material may be one or more of molybdenum (Mo), chromium (Cr), gold (Au), titanium (Ti), nickel (Ni), neodymium (Nd), and/or copper (Cu), and/or alloys thereof.

As illustrated in FIG. 22, a base substrate BSUB on which the first light emitting elements LE1 are formed is aligned on the semiconductor circuit substrate 110. In this case, the base substrate BSUB is aligned so that the first contact electrodes CTE1 of the first light emitting elements LE1 formed on the base substrate BSUB face the semiconductor circuit substrate 110. In this case, the pixel electrode layer ANOL is formed on an entire surface of semiconductor circuit substrate 110, and thus, alignment of the first contact electrodes CTE1 of the first light emitting elements LE1 is unnecessary. That is, the first contact electrodes CTE1 of the first light emitting elements LE1 may be aligned on the semiconductor circuit substrate 110 in an alignment-free manner.

As described above, the first light emitting element LE1 includes a plurality of semiconductor material layers formed by growing seed crystals by an epitaxial method. A method of forming the semiconductor material layers may be electron beam deposition, physical vapor deposition (PVD), chemical vapor deposition (CVD), plasma laser deposition (PLD), dual-type thermal evaporation, sputtering, metal organic chemical vapor deposition (MOCVD), or the like, and preferably, metal-organic chemical vapor deposition (MOCVD). However, the present disclosure is not limited thereto.

A precursor material for forming the plurality of semiconductor material layers is not particularly limited within a range that may be usually selected for forming a target material. As an example, the precursor material may be a metal precursor including an alkyl group such as a methyl group or an ethyl group. For example, the precursor material may be a compound such as trimethyl gallium (Ga(CH₃)₃), trimethyl aluminum (Al(CH₃)₃), or triethyl phosphate ((C₂H₅)₃PO₄), but is not limited thereto. The first light emitting element LE1 may include the first contact electrode CTE1 made of one or more of gold (Au), copper (Cu), aluminum (Al), and/or tin (Sn), and/or alloys thereof.

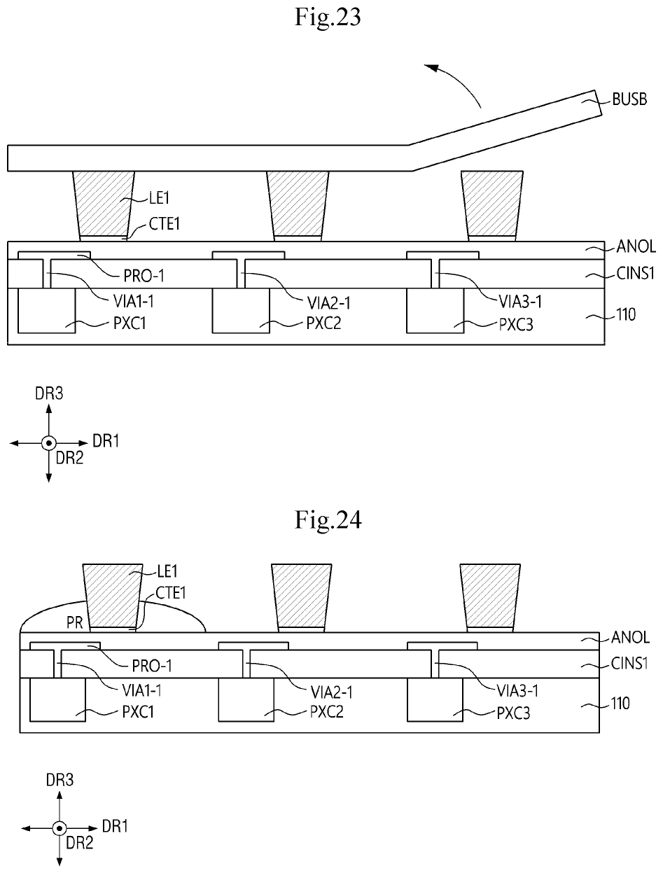

Subsequently, as illustrated in FIG. 23, the base substrate BSUB on which the first light emitting elements LE1 are formed is bonded to the semiconductor circuit substrate 110. Specifically, the first contact electrodes CTE1 of the first light emitting elements LE1 formed on the base substrate BSUB are brought into contact with the pixel electrode layer ANOL of the semiconductor circuit substrate 110. In this case, the first contact electrodes CTE1 of the first light emitting elements LE1 are in contact with the pixel electrode layer ANOL of the semiconductor circuit substrate 110.

The first contact electrodes CTE1 of the first light emitting elements LE1 are bonded to the pixel electrode layer ANOL, and the base substrate BSUB is separated from the plurality of first light emitting elements LE1.

The first contact electrodes CTE1 and the pixel electrode layer ANOL may be bonded to each other by irradiating the base substrate BSUB with a laser above the base substrate BSUB. High heat of the laser is conducted to the first contact electrodes CTE1, such that the first contact electrodes CTE1 may be adhered to the pixel electrode layer ANOL at interfaces between the first contact electrodes CTE1 and the pixel electrode layer ANOL.

A process of separating the base substrate BSUB may be a laser lift off (LLO) process. The laser lift off process uses a laser, and may use a KrF excimer laser (wavelength of 248 nm) as a source, but is not limited thereto. The base substrate BSUB is irradiated with the laser, such that the base substrate BSUB may be separated from the first light emitting elements LE1.

Next, as illustrated in FIG. 24, a photoresist PR is applied, exposed, and developed to be patterned on the pixel electrode layer ANOL on which the first light emitting element LE1 is disposed. The photoresist PR is applied to entirely cover the first contact electrode CTE1 of the first light emitting element LE1 and entirely cover the first pixel circuit unit PXC1 and the first protective electrode PRO-1.

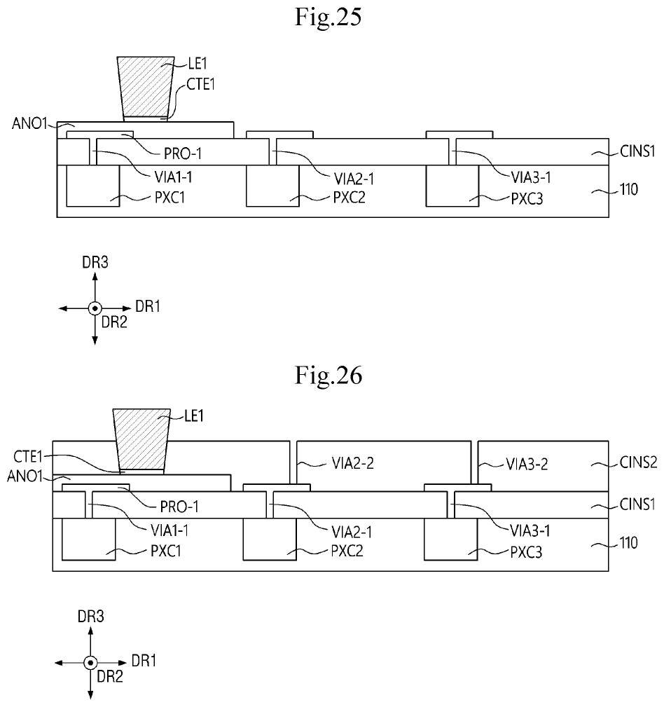

As illustrated in FIG. 25, the first pixel electrode ANO1 is patterned by removing the pixel electrode layer in portions that are not coated with the photoresist PR and the light emitting elements disposed on the pixel electrode layer in the portions that are not coated with the photoresist PR. The first light emitting element LE1 is electrically connected to the first pixel circuit unit PXC1 through the first contact electrode CTE1, the first pixel electrode ANO1, and the first protective electrode PRO-1.

Next, as illustrated in FIG. 26, the second insulating layer CINS2 is formed by applying an insulating material onto side surfaces of each of the first light emitting elements LE1, and the contact holes VIA2-2 and VIA3-2 are formed by etching suitable areas (e.g., predetermined areas) on the second insulating layer CINS2 through a photo & dry etch process. The protective electrodes PRO-1 may be exposed through the contact holes VIA2-2 and VIA3-2. The insulating material may be an inorganic film such as a silicon oxide film (SiO₂), an aluminum oxide film (Al₂O₃), or a hafnium oxide film (HfOₓ).

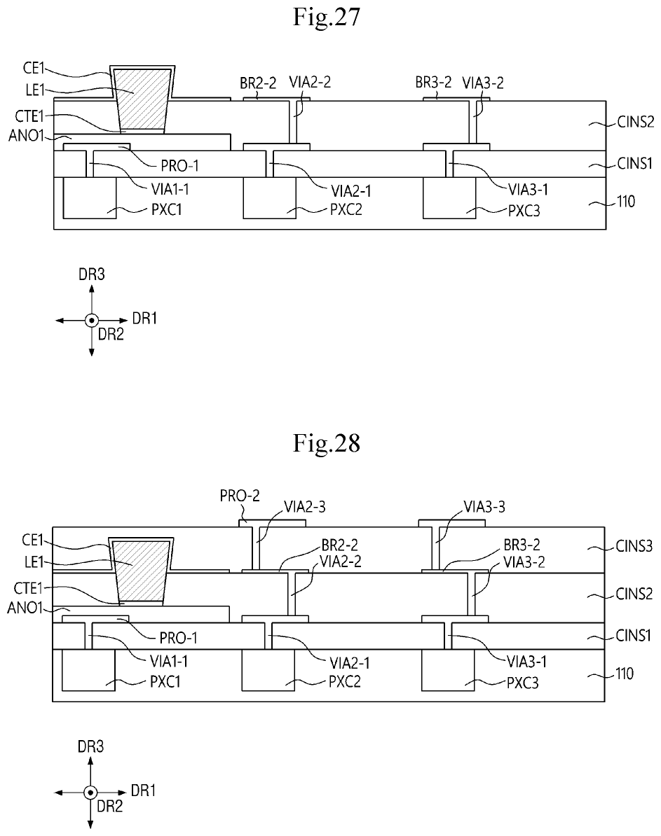

Then, as illustrated in FIG. 27, the first common electrode CE1 and the first bridge electrodes BR2-2 and BR3-2 are formed on an upper surface of each of the first light emitting elements LE1 and the second insulating layer CINS2.

A common electrode material is deposited on the upper surface of each of the first light emitting elements LE1 and the second insulating layer CINS2. The common electrode material may be formed to cover the first light emitting element LE1 and the contact holes VIA2-2 and VIA3-2, and may fill the contact holes VIA2-2 and VIA3-2. The first common electrode CE1 and the first bridge electrodes BR2-2 and BR 3-2 are formed by etching the common electrode material using a photoresist mask. The common electrode material may include a transparent conductive oxide (TCO) such as indium tin oxide (ITO) and/or indium zinc oxide (IZO).

The first common electrode CE1 covering the first light emitting element LE1 and the first bridge electrodes BR2-2 and BR3-2 covering the contact holes VIA2-2 and VIA3-2 are formed to be spaced from each other.

The first common electrode CE1 may be formed to cover the first light emitting element LE1, and the first bridge electrodes BR2-2 and BR3-2 may be formed on the contact holes VIA2-2 and VIA3-2. Accordingly, the first bridge electrodes BR2-2 and BR3-2 are connected to the protective electrodes PRO-1 through the contact holes VIA2-2 and VIA3-2.

Referring to FIG. 28, the third insulating layer CINS3 and the second protective electrodes PRO-2 are formed on the first common electrode CE1 and the first bridge electrodes BR2-2 and BR3-2 (S130 of FIG. 18). To this end, the third insulating layer CINS3 is formed by applying an insulating material onto the first common electrode CE1 and the first bridge electrodes BR2-2 and BR3-2, and the contact holes VIA2-3 and VIA3-3 are formed by etching suitable areas (e.g., predetermined areas) on the third insulating layer CINS3 through a photo & dry etch process. The first bridge electrodes BR2-2 and BR3-2 may be exposed through the contact holes VIA2-3 and VIA3-3. The insulating material may be an inorganic film such as a silicon oxide film (SiO₂), an aluminum oxide film (Al₂O₃), and/or a hafnium oxide film (HfOₓ). Thereafter, the second protective electrodes PRO-2 are formed on the third insulating layer CINS3 with a protective electrode material and patterning the protective electrode material. The protective electrode material may fill the contact holes VIA2-3 and VIA3-3. The second protective electrodes PRO-2 may be formed on the contact holes VIA2-3 and VIA3-3. Accordingly, the second protective electrodes PRO-2 are connected to the first bridge electrodes BR2-2 and BR3-2 through the contact holes VIA2-3 and VIA3-3.

Next, the second light emitting element layer 130 is formed on the third insulating layer CINS3 (S140 of FIG. 18).

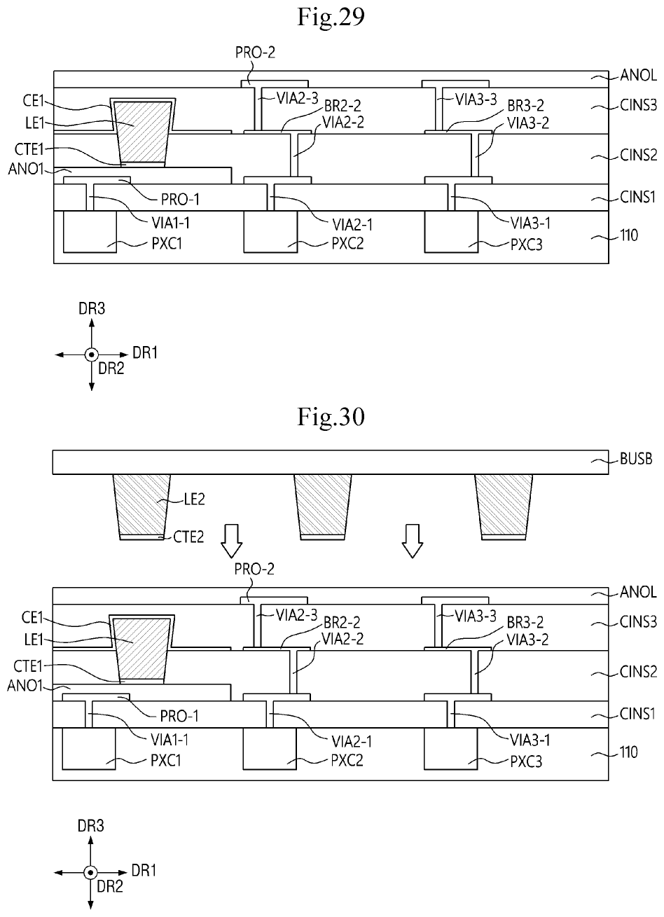

Specifically, referring to FIG. 29, a pixel electrode layer ANOL is formed by covering the third insulating layer CINS3 on which the second protective electrodes PRO-2 are formed, with a pixel electrode material.

As illustrated in FIG. 30, a base substrate BSUB on which the second light emitting elements LE2 are formed is aligned on the semiconductor circuit substrate 110. In this case, the base substrate BSUB is aligned so that the second contact electrodes CTE2 of the second light emitting elements LE2 formed on the base substrate BSUB face the semiconductor circuit substrate 110. In this case, the pixel electrode layer ANOL is formed on an entire surface of the semiconductor circuit substrate 110, and thus, alignment of the second contact electrodes CTE2 of the second light emitting elements LE2 is unnecessary. That is, the second contact electrodes CTE2 of the second light emitting elements LE2 may be aligned on the semiconductor circuit substrate 110 in an alignment-free manner.

As described above, the second light emitting element LE2 includes a plurality of semiconductor material layers formed by growing seed crystals by an epitaxial method. A method of forming the semiconductor material layer has been described above, and an overlapping description thereof will thus be omitted.

The second light emitting element LE2 may include the second contact electrode CTE2 made of one or more of gold (Au), copper (Cu), aluminum (Al), and/or tin (Sn), and/or alloys thereof.

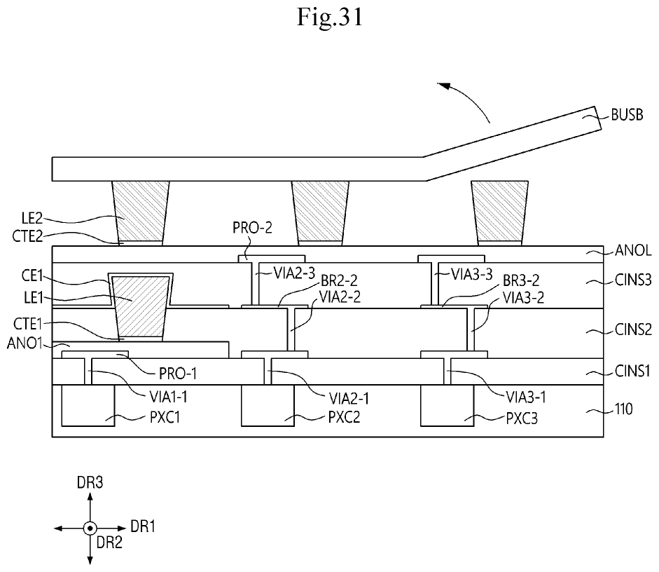

Subsequently, as illustrated in FIG. 31, the base substrate BSUB on which the second light emitting elements LE2 are formed is bonded to the semiconductor circuit substrate 110, and the base substrate BSUB is separated from the plurality of second light emitting elements LE2.

Specifically, the second contact electrodes CTE2 of the second light emitting elements LE2 formed on the base substrate BSUB are brought into contact with the pixel electrode layer ANOL of the semiconductor circuit substrate 110. In this case, the second contact electrodes CTE2 of the second light emitting elements LE2 are in contact with the pixel electrode layer ANOL of the semiconductor circuit substrate 110.

The second contact electrodes CTE2 of the second light emitting elements LE2 are bonded to the pixel electrode layer ANOL, and the base substrate BSUB is separated from the plurality of second light emitting elements LE2. A method of bonding the second light emitting elements LE2 and a method of separating the base substrate BSUB have been described above, and an overlapping description thereof will thus be omitted.

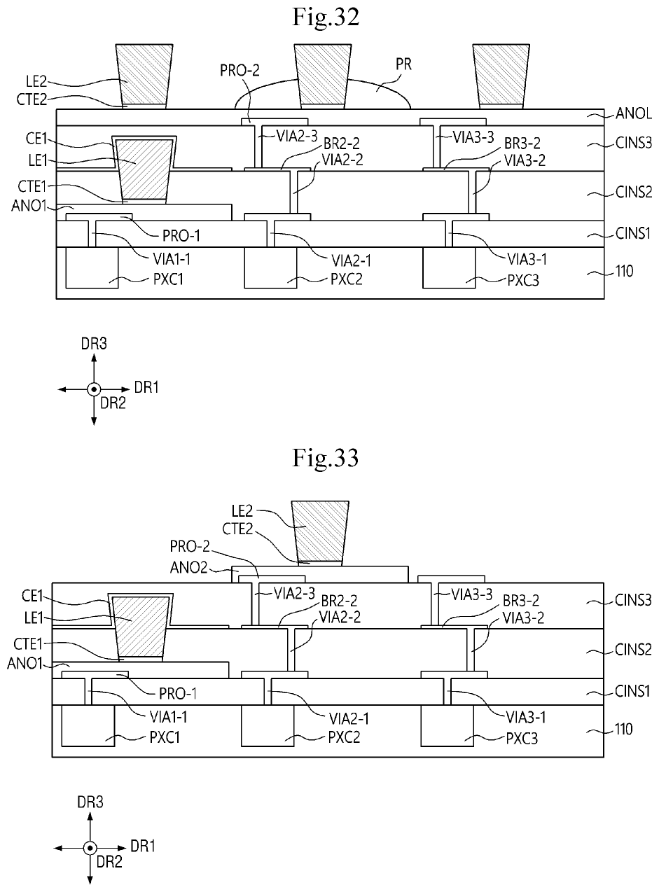

Next, as illustrated in FIG. 32, a photoresist PR is applied, exposed, and developed to be patterned on the pixel electrode layer ANOL on which the second light emitting element LE2 is disposed. The photoresist PR is applied to entirely cover the second contact electrode CTE2 of the second light emitting element LE2 and entirely cover the second pixel circuit unit PXC2 and the second protective electrode PRO-2.

As illustrated in FIG. 33, the second pixel electrode ANO2 is patterned by removing the pixel electrode layer in portions that are not coated with the photoresist PR and the light emitting elements disposed on the pixel electrode layer in the portions that are not coated with the photoresist PR. The second light emitting element LE2 is electrically connected to the second pixel circuit unit PXC2 through the second contact electrode CTE2, the second pixel electrode ANO2, the second protective electrode PRO-2, the first bridge electrode BR2-2, and the first protective electrode PRO-1.

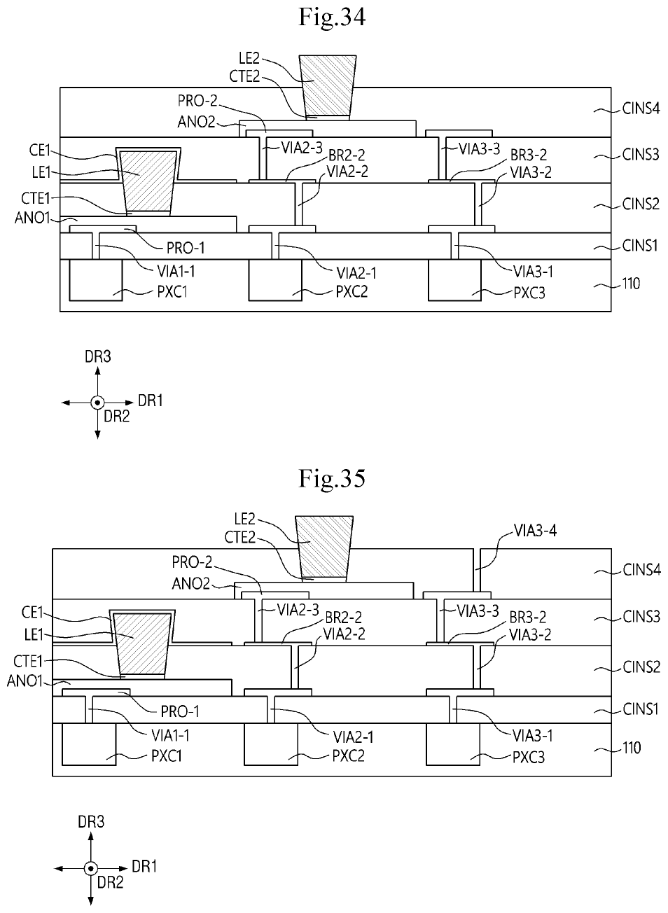

Next, as illustrated in FIGS. 34 and 35, the fourth insulating layer CINS4 is formed by applying an insulating material onto side surfaces of each of the second light emitting elements LE2, and the contact hole VIA3-4 is formed by etching a suitable area (e.g., a predetermined area) on the fourth insulating layer CINS4 through a photo & dry etch process. The protective electrode PRO-2 may be exposed through the contact hole VIA3-4.

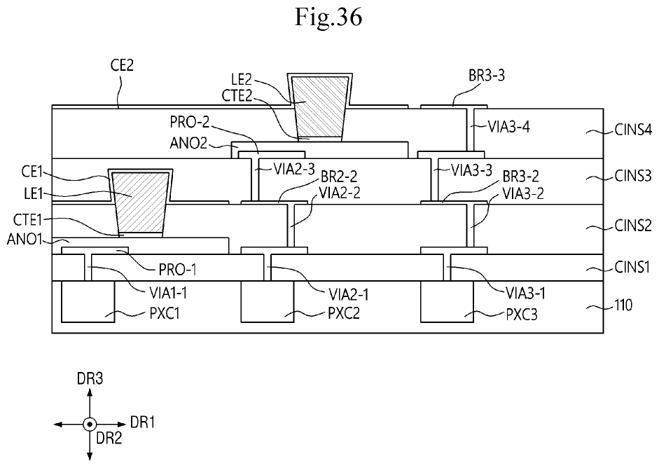

Then, as illustrated in FIG. 36, the second common electrode CE2 and the second bridge electrode BR3-3 are formed on an upper surface of each of the second light emitting elements LE2 and the fourth insulating layer CINS4.

The fifth insulating layer CINS5 and the third protective electrode PRO-3 are formed on the second common electrode CE2 and the second bridge electrode BR3-3 (S150 of FIG. 18).

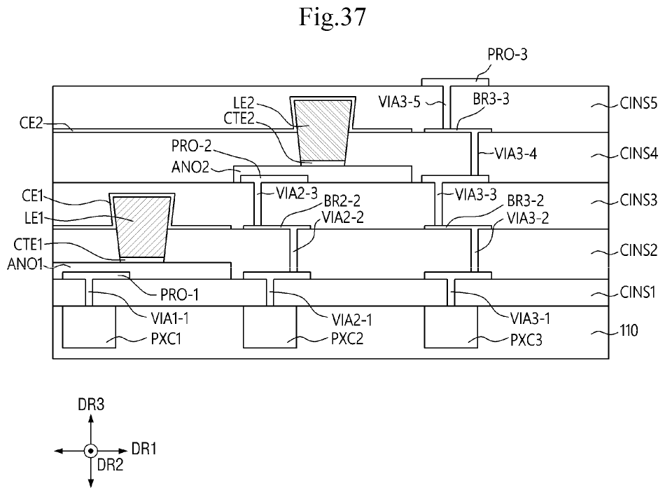

Specifically, as illustrated in FIG. 37, the fifth insulating layer CINS5 is formed by applying an insulating material onto the second common electrode CE2 and the second bridge electrode BR3-3, and the contact hole VIA3-5 is formed by etching a suitable area (e.g., a predetermined area) on the fifth insulating layer CINS5 through a photo & dry etch process. The second bridge electrode BR3-3 may be exposed through the contact hole VIA3-5. Thereafter, the third protective electrode PRO-3 is formed by the fifth insulating layer CINS5 with a protective electrode material and patterning the protective electrode material. The protective electrode material may fill the contact hole VIA3-5. The third protective electrode PRO-3 may be formed on the contact hole VIA3-5. Accordingly, the third protective electrode PRO-3 is connected to the second bridge electrode BR3-3 through the contact hole VIA3-5.

Next, the third light emitting element layer 140 is formed on the fifth insulating layer CINS5 (S160 of FIG. 18).

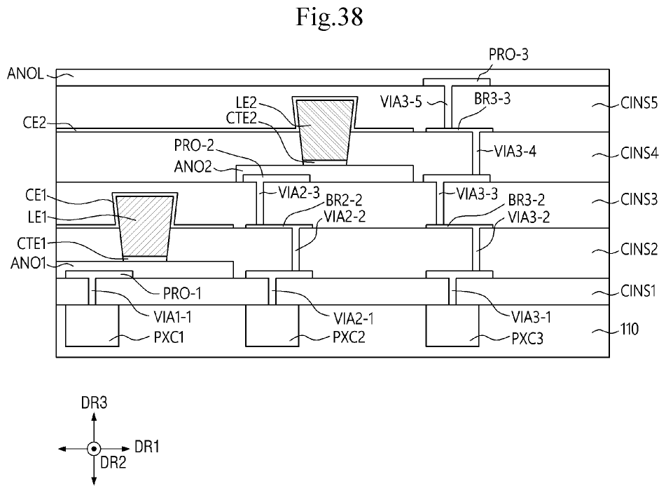

Specifically, as illustrated in FIG. 38, a pixel electrode layer ANOL is formed by covering the fifth insulating layer CINS5 on which the third protective electrode PRO-3 is formed, with a pixel electrode material.

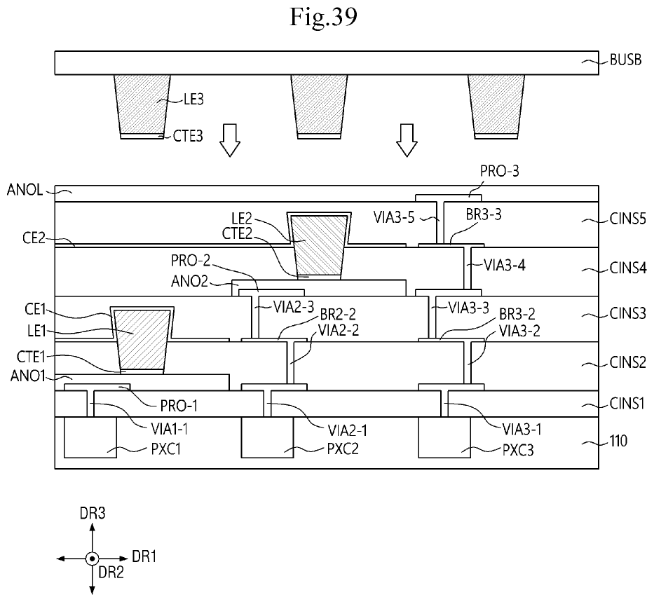

As illustrated in FIG. 39, a base substrate BSUB on which the third light emitting elements LE3 are formed is aligned on the semiconductor circuit substrate 110. In this case, the base substrate BSUB is aligned so that the third contact electrodes CTE3 of the third light emitting elements LE3 formed on the base substrate BSUB face the semiconductor circuit substrate 110. In this case, the pixel electrode layer ANOL is formed on an entire surface of semiconductor circuit substrate 110, and thus, alignment of the third contact electrodes CTE3 of the third light emitting elements LE3 is unnecessary. That is, the third contact electrodes CTE3 of the third light emitting elements LE3 may be aligned on the semiconductor circuit substrate 110 in an alignment-free manner.

As described above, the third light emitting element LE3 includes a plurality of semiconductor material layers formed by growing seed crystals by an epitaxial method. A method of forming the semiconductor material layer has been described above, and an overlapping description thereof will thus be omitted.

The third light emitting element LE3 may include the third contact electrode CTE3 made of one or more of gold (Au), copper (Cu), aluminum (Al), and/or tin (Sn), and/or alloys thereof.

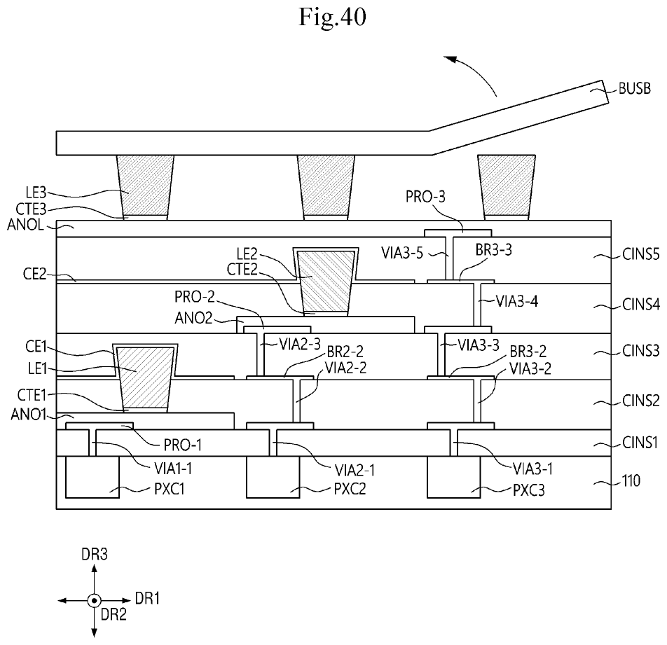

Subsequently, as illustrated in FIG. 40, the base substrate BSUB on which the third light emitting elements LE3 are formed is bonded to the semiconductor circuit substrate 110, and the base substrate BSUB is separated from the plurality of third light emitting elements LE3.

Specifically, the third contact electrodes CTE3 of the third light emitting elements LE3 formed on the base substrate BSUB are brought into contact with the pixel electrode layer ANOL of the semiconductor circuit substrate 110. In this case, the third contact electrodes CTE3 of the third light emitting elements LE3 are in contact with the pixel electrode layer ANOL of the semiconductor circuit substrate 110.

The third contact electrodes CTE3 of the third light emitting elements LE3 are bonded to the pixel electrode layer ANOL, and the base substrate BSUB is separated from the plurality of third light emitting elements LE3. A method of bonding the third light emitting elements LE3 and a method of separating the base substrate BSUB have been described above, and an overlapping description thereof will thus be omitted.

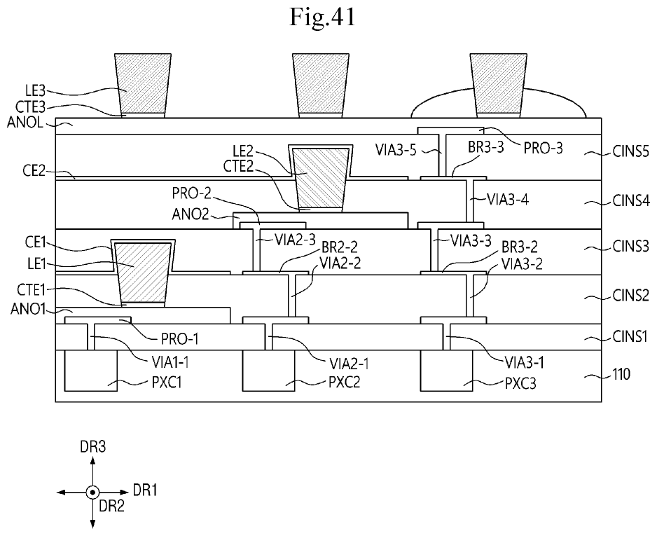

Next, as illustrated in FIG. 41, a photoresist PR is applied, exposed, and developed to be patterned on the pixel electrode layer ANOL on which the third light emitting element LE3 is disposed. The photoresist PR is applied to entirely cover the third contact electrode CTE3 of the third light emitting element LE3 and entirely cover the third pixel circuit unit PXC3 and the third protective electrode PRO-3.

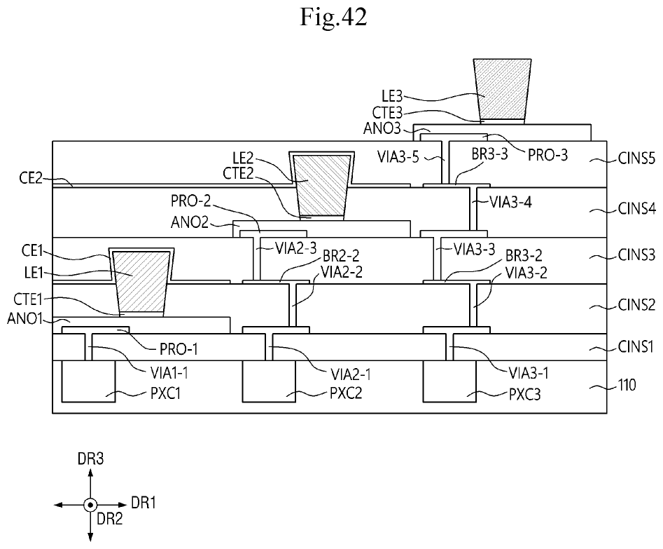

As illustrated in FIG. 42, the third pixel electrode ANO3 is patterned by removing the pixel electrode layer in portions that are not coated with the photoresist PR and the light emitting elements disposed on the pixel electrode layer in the portions that are not coated with the photoresist PR. The third light emitting element LE3 is electrically connected to the third pixel circuit unit PXC3 through the third contact electrode CTE3, the third pixel electrode ANO3, the third protective electrode PRO-3, the second bridge electrode BR3-3, the second protective electrode PRO-2, the first bridge electrode BR3-2, and the first protective electrode PRO-1.

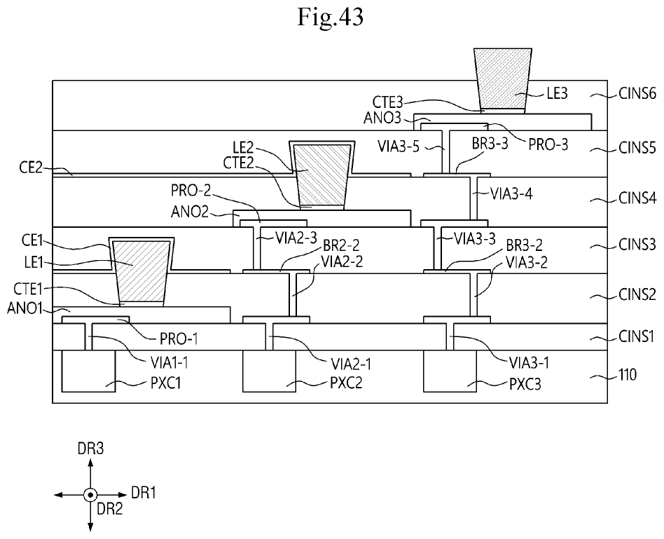

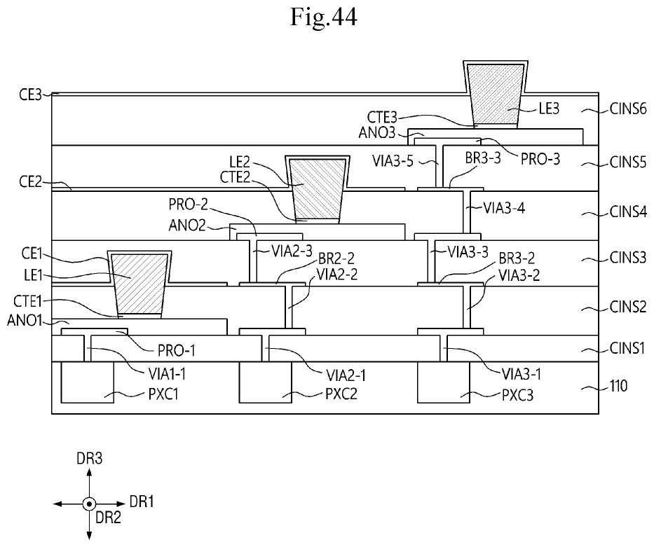

As illustrated in FIGS. 43 and 44, the sixth insulating layer CINS6 is formed by applying an insulating material onto side surfaces of each of the third light emitting elements LE3, and the third common electrode CE3 is formed on an upper surface of each of the third light emitting elements LE3 and the sixth insulating layer CINS6.

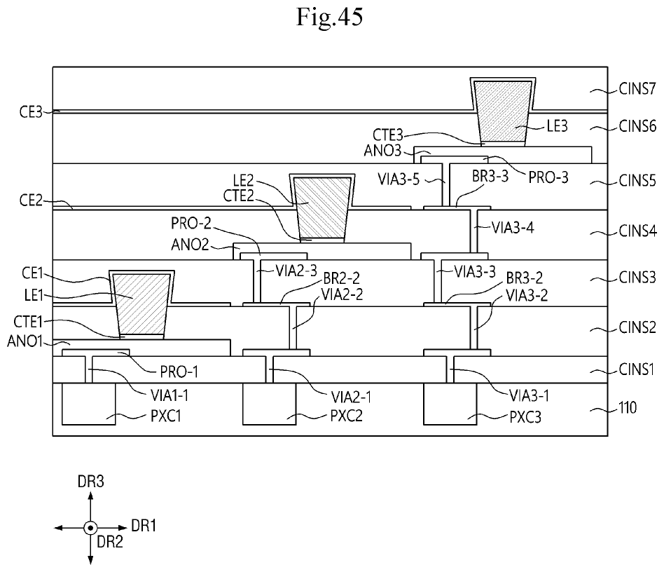

As illustrated in FIG. 45, the seventh insulating layer CINS7 is formed by applying an insulating material onto the third common electrode CE3 (S170 of FIG. 18).

According to one or more embodiments, light emitting elements emitting different lights are disposed at different layers, and are disposed on pixel electrodes formed at the different layers. The light emitting elements emitting the different lights are in contact with common electrodes disposed at the different layers.

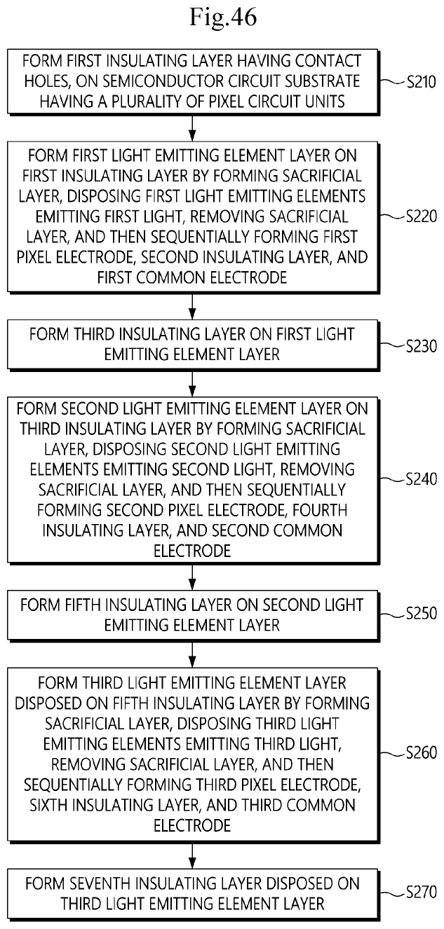

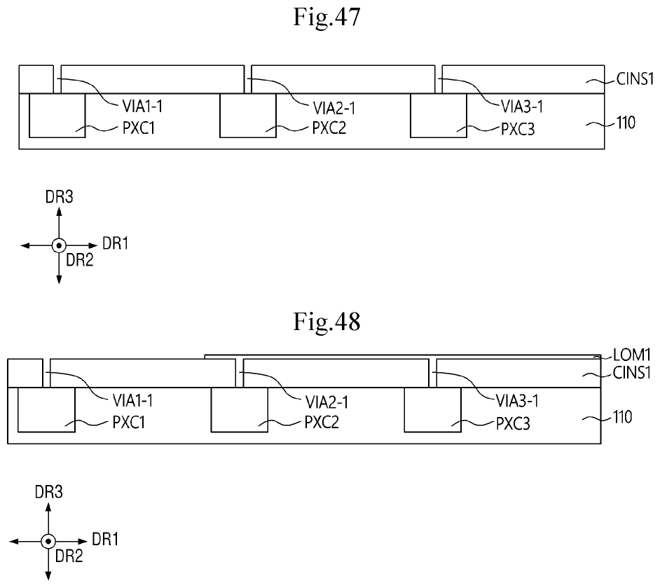

FIG. 46 is a flowchart illustrating a method of fabricating a display device according to one or more embodiments of the present disclosure, and FIGS. 47 to 62 are cross-sectional views for describing the method of fabricating a display device according to one or more embodiments.

Hereinafter, a method of fabricating a display panel according to one or more embodiments will be described in detail with reference to FIGS. 47 to 62.

First, the first insulating layer CINS1 having the contact holes VIA1-1, VIA2-1, and VIA3-1 is formed on the semiconductor circuit substrate 110 (S210 of FIG. 46).

As illustrated in FIG. 47, the first insulating layer CINS1 is formed by applying a first insulating material onto the semiconductor circuit substrate 110, and the contact holes VIA1-1, VIA2-1, and VIA3-1 are formed by etching suitable areas (e.g., predetermined areas) on the first insulating layer CINS1 through a photo & dry etch process. The plurality of pixel circuit units PXC1, PXC2, and PXC3 may be exposed through the contact holes VIA1-1, VIA2-1, and VIA3-1. The first insulating material may be an inorganic film such as a silicon oxide film (SiO₂), an aluminum oxide film (Al₂O₃), and/or a hafnium oxide film (HfOₓ).

Next, the first light emitting element layer 120 is formed on the first insulating layer CINS1 through a sacrificial layer LOM1 (S220 of FIG. 46).

As illustrated in FIG. 48, the sacrificial layer LOM1 is formed on the first insulating layer CINS1 of the second pixel circuit unit PXC2 and the third pixel circuit unit PXC3 by covering the first insulating layer CINS1 with a sacrificial material and patterning the sacrificial material. The sacrificial layer LOM1 may be formed on the contact holes VIA2-1 and VIA3-1. The sacrificial material may fill the contact holes VIA2-1 and VIA3-1. The sacrificial material may be a transparent conductive oxide (TCO) having an etching selectivity with respect to the first pixel electrode ANO1.

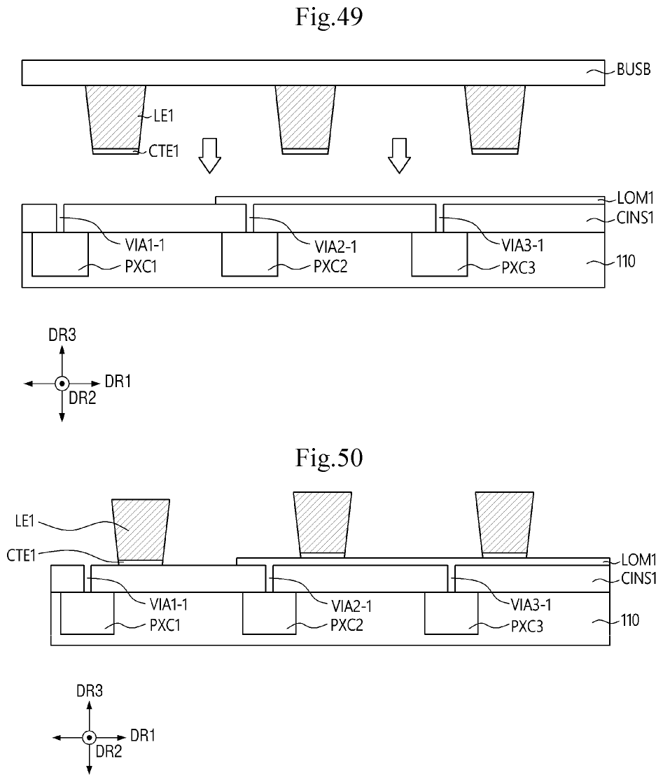

As illustrated in FIGS. 49 and 50, a base substrate BSUB on which the first light emitting elements LE1 are formed is bonded to the semiconductor circuit substrate 110. Specifically, the base substrate BSUB on which the first light emitting elements LE1 are formed is aligned on the first insulating layer CINS1 on which the sacrificial layer LOM1 is formed. In this case, the base substrate BSUB is aligned so that the first contact electrodes CTE1 of the first light emitting elements LE1 formed on the base substrate BSUB face the semiconductor circuit substrate 110. In this case, pixel electrodes ANO are formed after the first light emitting elements LE1 are bonded, and thus, alignment between the first contact electrodes CTE1 of the first light emitting elements LE1 and the pixel electrodes ANO is unnecessary. That is, the first contact electrodes CTE1 of the first light emitting elements LE1 may be aligned on the semiconductor circuit substrate 110 in an alignment-free manner.

As described above, the first light emitting element LE1 includes a plurality of semiconductor material layers formed by growing seed crystals by an epitaxial method. A method of forming the semiconductor material layers may be electron beam deposition, physical vapor deposition (PVD), chemical vapor deposition (CVD), plasma laser deposition (PLD), dual-type thermal evaporation, sputtering, metal organic chemical vapor deposition (MOCVD), or the like, and preferably, metal-organic chemical vapor deposition (MOCVD). However, the present disclosure is not limited thereto.

A precursor material for forming the plurality of semiconductor material layers is not particularly limited within a range that may be usually selected for forming a target material. As an example, the precursor material may be a metal precursor including an alkyl group such as a methyl group or an ethyl group. For example, the precursor material may be a compound such as trimethyl gallium (Ga(CH₃)₃), trimethyl aluminum (Al(CH₃)₃), and/or triethyl phosphate ((C₂H₅)₃PO₄), but is not limited thereto. The first light emitting element LE1 may include the first contact electrode CTE1 made of one or more of gold (Au), copper (Cu), aluminum (Al), and/or tin (Sn), and/or alloys thereof.

The first contact electrodes CTE1 of the first light emitting elements LE1 formed on the base substrate BSUB are brought into contact with the first insulating layer CINS1 of the semiconductor circuit substrate 110.

The first contact electrodes CTE1 of the first light emitting elements LE1 are bonded to the first insulating layer CINS1, and the base substrate BSUB is separated from the plurality of first light emitting elements LE1. The first contact electrodes CTE1 and the first insulating layer CINS1 may be bonded to each other by irradiating the base substrate BSUB with a laser above the base substrate BSUB. High heat of the laser is conducted to the first contact electrodes CTE1, such that the first contact electrodes CTE1 may be adhered to the first insulating layer CINS1 at interfaces between the first contact electrodes CTE1 and the first insulating layer CINS1.

A process of separating the base substrate BSUB may be a laser lift off (LLO) process. The laser lift off process uses a laser, and may use a KrF excimer laser (wavelength of 248 nm) as a source, but is not limited thereto. The base substrate BSUB is irradiated with the laser, such that the base substrate BSUB may be separated from the first light emitting elements LE1.

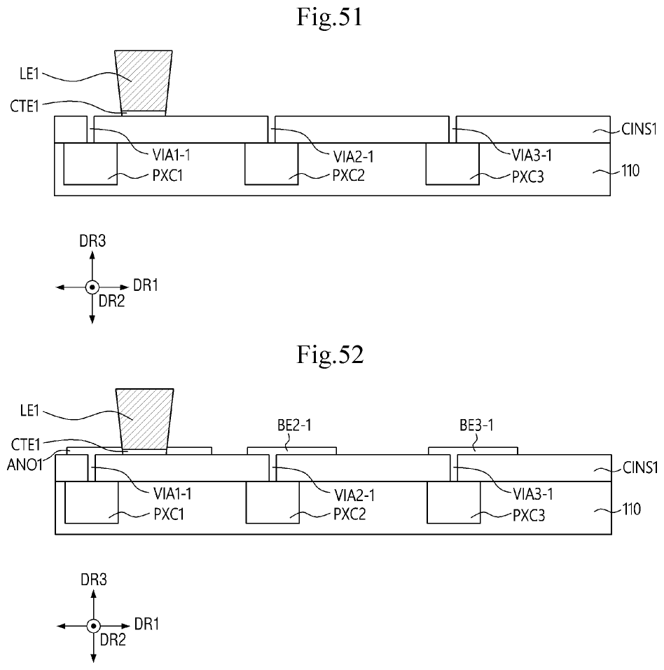

As illustrated in FIG. 51, the sacrificial layer may be removed in a wet-etching or lift-off manner. When the sacrificial layer is removed, an original structure should not be affected. When the sacrificial layer is removed, the first light emitting elements LE1 disposed on the sacrificial layer are also removed.

As illustrated in FIG. 52, a pixel electrode material is applied to cover side surfaces of the first contact electrode CTE1 of the first light emitting element LE1 disposed on the first insulating layer CINS1 and the contact holes VIA1-1, VIA2-1, and VIA3-1. Accordingly, the contact holes VIA1-1, VIA2-1, and VIA3-1 may be filled with the pixel electrode material. Next, the first pixel electrodes ANO1 and the first connection electrodes BE2-1 and BE3-1 are formed on the first insulating layer CINS1 by applying, exposing, and developing a photoresist. The first pixel electrode ANO1 is in contact with the side surfaces of the first contact electrode CTE1 of the first light emitting element LE1. The pixel electrode material may be one or more of molybdenum (Mo), chromium (Cr), gold (Au), titanium (Ti), nickel (Ni), neodymium (Nd), and/or copper (Cu), and/or alloys thereof. The first light emitting element LE1 is electrically connected to the first pixel circuit unit PXC1 through the first contact electrode CTE1 and the first pixel electrode ANO1.

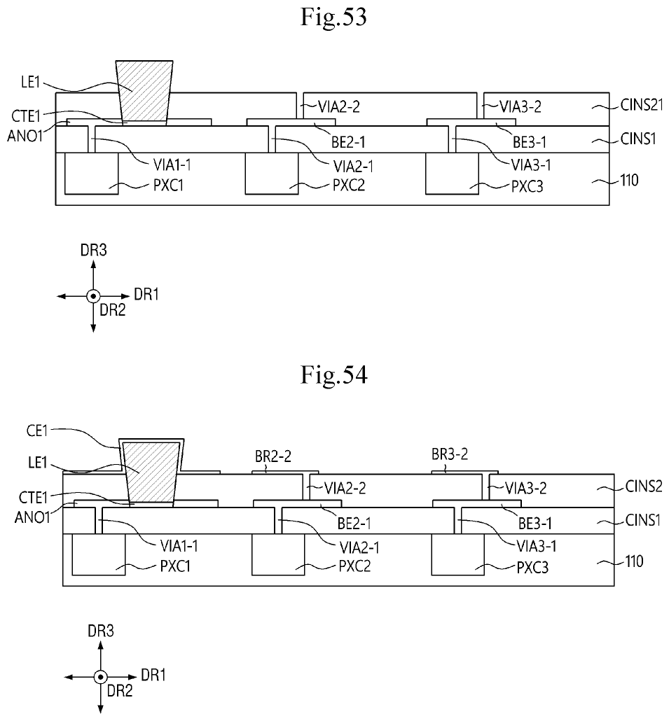

As illustrated in FIG. 53, the second insulating layer CINS2 is formed by applying an insulating material onto side surfaces of each of the first light emitting elements LE1, and the contact holes VIA2-2 and VIA3-2 are formed by etching suitable areas (e.g., predetermined areas) on the second insulating layer CINS2 through a photo & dry etch process. The first connection electrodes BE2-1 and BE3-1 may be exposed through the contact holes VIA2-2 and VIA3-2. The insulating material may be an inorganic film such as a silicon oxide film (SiO₂), an aluminum oxide film (Al₂O₃), and/or a hafnium oxide film (HfOₓ).

As illustrated in FIG. 54, the first common electrode CE1 and the first bridge electrodes BR2-2 and BR3-2 are formed on an upper surface of each of the first light emitting elements LE1 and the second insulating layer CINS2.

A common electrode material is deposited on the upper surface of each of the first light emitting elements LE1 and the second insulating layer CINS2. The common electrode material may be formed to cover the first light emitting element LE1 and the contact holes VIA2-2 and VIA3-2, and may fill the contact holes VIA2-2 and VIA3-2. The first common electrode CE1 and the first bridge electrodes BR2-2 and BR 3-2 are formed by etching the common electrode material using a photoresist mask. The common electrode material may include a transparent conductive oxide (TCO) such as indium tin oxide (ITO) and/or indium zinc oxide (IZO).

The first common electrode CE1 covering the first light emitting element LE1 and the first bridge electrodes BR2-2 and BR3-2 covering the contact holes VIA2-2 and VIA3-2 are formed to be spaced from each other.

The first common electrode CE1 may be formed to cover the first light emitting element LE1, and the first bridge electrodes BR2-2 and BR3-2 may be formed on the contact holes VIA2-2 and VIA3-2. Accordingly, the first bridge electrodes BR2-2 and BR3-2 are connected to the first connection electrodes BE2-1 and BE3-1 through the contact holes VIA2-2 and VIA3-2.

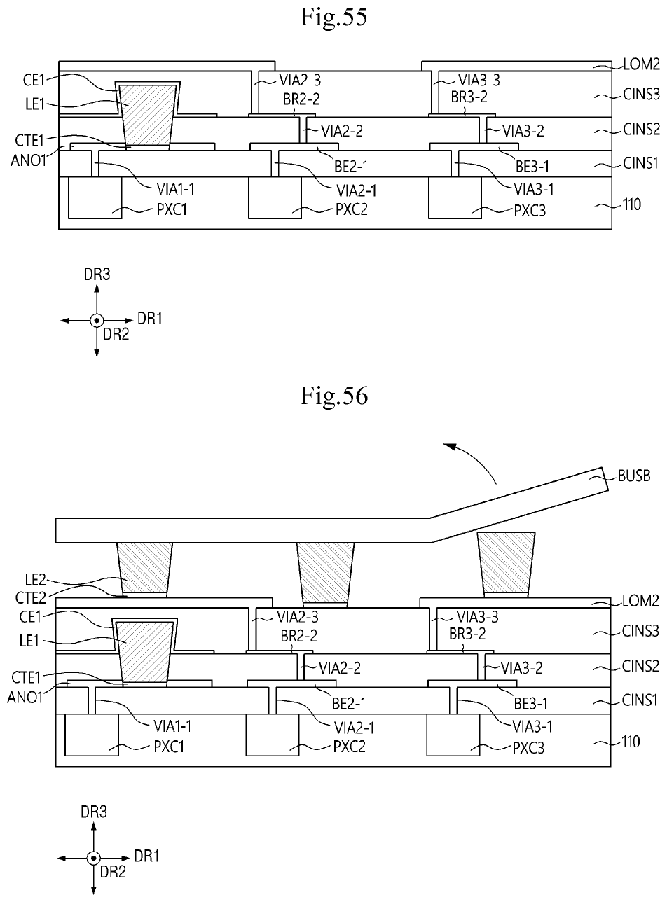

Next, referring to FIG. 55, the third insulating layer CINS3 is formed on the first common electrode CE1 and the first bridge electrodes BR2-2 and BR3-2 (S230 of FIG. 46). Specifically, the third insulating layer CINS3 is formed by applying an insulating material onto the first common electrode CE1 and the first bridge electrodes BR2-2 and BR3-2, and the contact holes VIA2-3 and VIA3-3 are formed by etching suitable areas (e.g., predetermined areas) on the third insulating layer CINS3 through a photo & dry etch process. The first bridge electrodes BR2-2 and BR3-2 may be exposed through the contact holes VIA2-3 and VIA3-3. The insulating material may be an inorganic film such as a silicon oxide film (SiO₂), an aluminum oxide film (Al₂O₃), and/or a hafnium oxide film (HfOₓ).

Thereafter, a sacrificial layer LOM2 is formed on the third insulating layer CINS3, and the second light emitting element layer 130 is formed (S240 of FIG. 46).

Specifically, the sacrificial layer LOM2 is formed on the third insulating layer CINS3 of the third pixel circuit unit PXC3. Thereafter, the sacrificial layer LOM2 is formed on the first pixel circuit unit PXC1 and the third pixel circuit unit PXC3 by covering the third insulating layer CINS3 with a sacrificial material and patterning the sacrificial material. The sacrificial material may fill the contact holes VIA2-3 and VIA3-3. The sacrificial layer LOM2 may be formed on the contact holes VIA2-3 and VIA3-3.

Referring to FIG. 56, a base substrate BSUB on which the second light emitting elements LE2 are formed is bonded to the semiconductor circuit substrate 110. Specifically, the base substrate BSUB on which the second light emitting elements LE2 are formed is aligned on the third insulating layer CINS3 on which the sacrificial layer LOM2 is formed. In this case, the base substrate BSUB is aligned so that the second contact electrodes CTE2 of the second light emitting elements LE2 formed on the base substrate BSUB face the semiconductor circuit substrate 110. In this case, pixel electrodes ANO are formed after the second light emitting elements LE2 are bonded, and thus, alignment between the second contact electrodes CTE2 of the second light emitting elements LE2 and the pixel electrodes ANO is unnecessary. That is, the second contact electrodes CTE2 of the second light emitting elements LE2 may be aligned on the semiconductor circuit substrate 110 in an alignment-free manner.

As described above, the second light emitting element LE2 includes a plurality of semiconductor material layers formed by growing seed crystals by an epitaxial method. A method of forming the semiconductor material layer has been described above, and an overlapping description thereof will thus be omitted.

The second light emitting element LE2 may include the second contact electrode CTE2 made of one or more of gold (Au), copper (Cu), aluminum (Al), and/or tin (Sn), and/or alloys thereof. Subsequently, the base substrate BSUB on which the second light emitting elements LE2 are formed is bonded to the semiconductor circuit substrate 110, and the base substrate BSUB is separated from the plurality of second light emitting elements LE2. Specifically, the second contact electrodes CTE2 of the second light emitting elements LE2 overlapping the second pixel circuit unit PXC2 are bonded onto the third insulating layer CINS3, and the base substrate BSUB is separated from the plurality of second light emitting elements LE2. A method of bonding the second light emitting elements LE2 and a method of separating the base substrate BSUB have been described above, and an overlapping description thereof will thus be omitted.

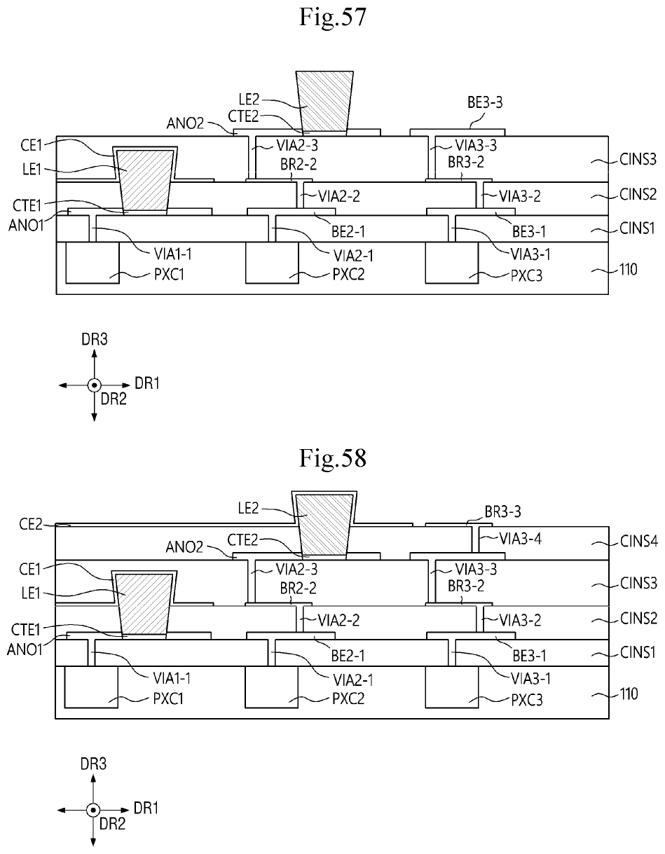

Referring to FIG. 57, the sacrificial layer formed on the third insulating layer CINS3 may be removed in a wet-etching or lift-off manner. When the sacrificial layer is removed, an original structure should not be affected. When the sacrificial layer is removed, the second light emitting elements LE2 disposed on the sacrificial layer are also removed.

A pixel electrode material is applied to cover side surfaces of the second contact electrode CTE2 of the second light emitting element LE2 disposed on the third insulating layer CINS3 and the contact holes VIA2-3 and VIA3-3. Accordingly, the contact holes VIA2-3 and VIA3-3 may be filled with the pixel electrode material. Next, the second pixel electrode ANO2 and the second connection electrode BE3-3 are formed on the third insulating layer CINS3 by applying, exposing, and developing a photoresist. The second pixel electrode ANO2 is in contact with the side surfaces of the second contact electrode CTE2 of the second light emitting element LE2. The second light emitting element LE2 is connected to the second pixel circuit unit PXC2 through the second contact electrode CTE2, the second pixel electrode ANO2, the first bridge electrode BR2-2, and the first connection electrode BE2-1.

Referring to FIG. 58, the second common electrode CE2 and the second bridge electrode BR3-3 are formed on an upper surface of each of the second light emitting elements LE2 and the fourth insulating layer CINS4.

A common electrode material is deposited on the upper surface of each of the second light emitting elements LE2 and the fourth insulating layer CINS4. The common electrode material may be formed to cover the second light emitting element LE2 and the contact hole VIA3-4 and may fill the contact hole VIA3-4. The second common electrode CE2 and the second bridge electrode BR3-3 are formed by etching the common electrode material using a photoresist mask.

The second common electrode CE2 covering the second light emitting element LE2 and the second bridge electrode BR3-3 covering the contact hole VIA3-4 are formed to be spaced from each other.

The second common electrode CE2 may be formed to cover the second light emitting element LE2, and the second bridge electrode BR3-3 may be formed on the contact hole VIA3-4. Accordingly, the second bridge electrode BR3-3 is connected to the second connection electrode BE3-3 through the contact hole VIA3-4.

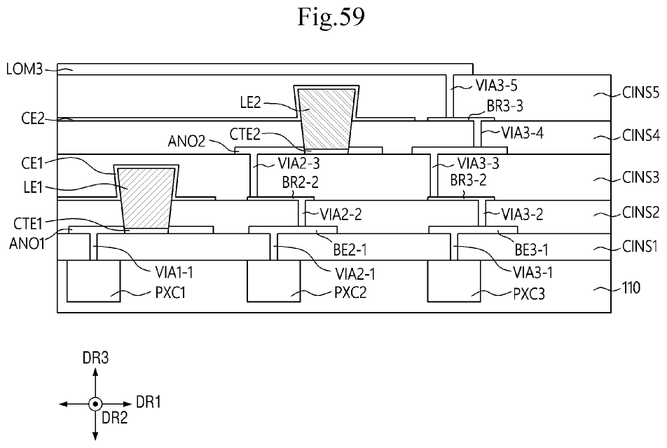

Referring to FIG. 59, the fifth insulating layer CINS5 is formed on the second common electrode CE2 and the second bridge electrode BR3-3 (S250 of FIG. 46). Specifically, the fifth insulating layer CINS5 is formed by applying an insulating material onto the second common electrode CE2 and the second bridge electrode BR3-3, and the contact hole VIA3-5 is formed by etching a suitable area (e.g., a predetermined area) on the fifth insulating layer CINS5 through a photo & dry etch process. The second bridge electrode BR3-3 may be exposed through the contact hole VIA3-5. The insulating material may be an inorganic film such as a silicon oxide film (SiO₂), an aluminum oxide film (Al₂O₃), or a hafnium oxide film (HfOₓ).

Thereafter, a sacrificial layer LOM3 is formed on the fifth insulating layer CINS5, and the third light emitting element layer 140 is formed (S260 of FIG. 46).

Specifically, the sacrificial layer LOM3 is formed on the first pixel circuit unit PXC1 and the second pixel circuit unit PXC2 by covering the fifth insulating layer CINS5 with a sacrificial material and patterning the sacrificial material.

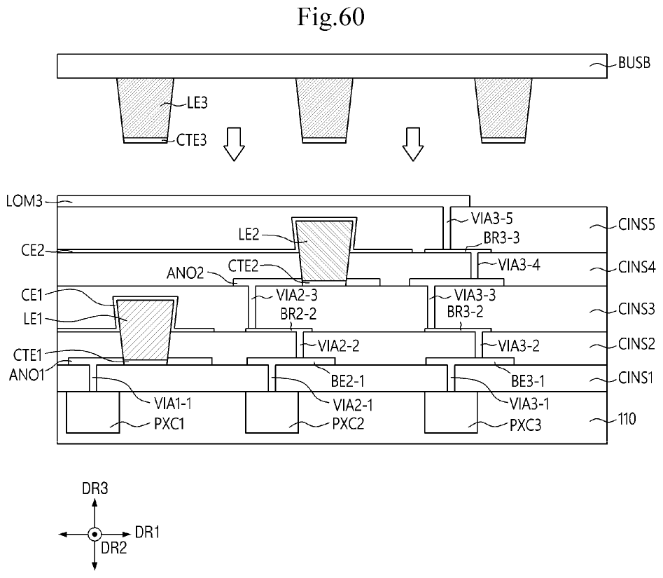

Referring to FIG. 60, a base substrate BSUB on which the third light emitting elements LE3 are formed is bonded to the semiconductor circuit substrate 110. Specifically, the base substrate BSUB on which the third light emitting elements LE3 are formed is aligned on the fifth insulating layer CINS5 on which the sacrificial layer LOM3 is formed. In this case, the base substrate BSUB is aligned so that the third contact electrodes CTE3 of the third light emitting elements LE3 formed on the base substrate BSUB face the semiconductor circuit substrate 110. In this case, pixel electrodes ANO are formed after the third light emitting elements LE3 are bonded, and thus, alignment between the third contact electrodes CTE3 of the third light emitting elements LE3 and the pixel electrodes ANO is unnecessary. That is, the third contact electrodes CTE3 of the third light emitting elements LE3 may be aligned on the semiconductor circuit substrate 110 in an alignment-free manner.

As described above, the third light emitting element LE3 includes a plurality of semiconductor material layers formed by growing seed crystals by an epitaxial method. A method of forming the semiconductor material layer has been described above, and an overlapping description thereof will thus be omitted.

The third light emitting element LE3 may include the third contact electrode CTE3 made of one or more of gold (Au), copper (Cu), aluminum (Al), and/or tin (Sn), and/or alloys thereof. Subsequently, the base substrate BSUB on which the third light emitting elements LE3 are formed is bonded to the semiconductor circuit substrate 110, and the base substrate BSUB is separated from the plurality of third light emitting elements LE3. Specifically, the third contact electrodes CTE3 of the third light emitting elements LE3 overlapping the third pixel circuit unit PXC3 are bonded onto the fifth insulating layer CINS5, and the base substrate BSUB is separated from the plurality of third light emitting elements LE3. A method of bonding the third light emitting elements LE3 and a method of separating the base substrate BSUB have been described above, and an overlapping description thereof will thus be omitted.

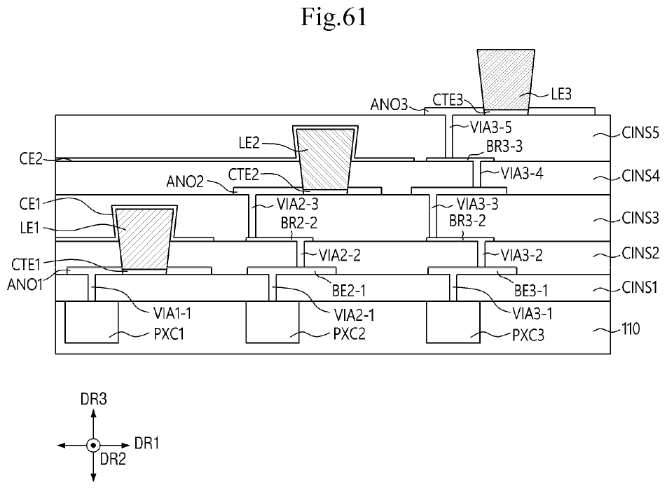

Referring to FIG. 61, the sacrificial layer formed on the fifth insulating layer CINS5 may be removed in a wet-etching or lift-off manner. When the sacrificial layer is removed, an original structure should not be affected. When the sacrificial layer is removed, the third light emitting elements LE3 disposed on the sacrificial layer are also removed.

A pixel electrode material is applied to cover side surfaces of the third contact electrode CTE3 of the third light emitting element LE3 disposed on the fifth insulating layer CINS5. Next, the third pixel electrode ANO3 is formed on the fifth insulating layer CINS5 by applying, exposing, and developing a photoresist. The third pixel electrode ANO3 is in contact with the side surfaces of the third contact electrode CTE3 of the third light emitting element LE3. The third light emitting element LE3 is electrically connected to the third pixel circuit unit PXC3 through the third contact electrode CTE3, the third pixel electrode ANO3, the second bridge electrode BR3-3, the second connection electrode BE3-3, the first bridge electrode BR3-2, and the first connection electrode BE3-1.

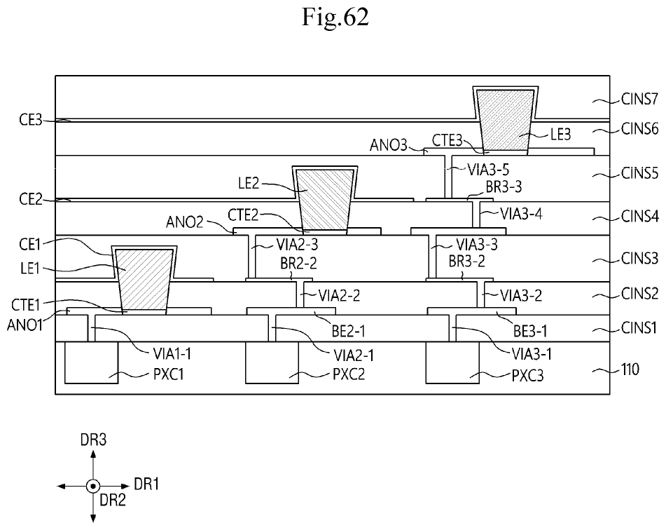

Referring to FIG. 62, the sixth insulating layer CINS6 is formed by applying an insulating material onto side surfaces of each of the third light emitting elements LE3, and the third common electrode CE3 is formed on an upper surface of each of the third light emitting elements LE3 and the sixth insulating layer CINS6.

Thereafter, the seventh insulating layer CINS7 is formed by applying an insulating material onto the third common electrode CE3 (S270 of FIG. 46).

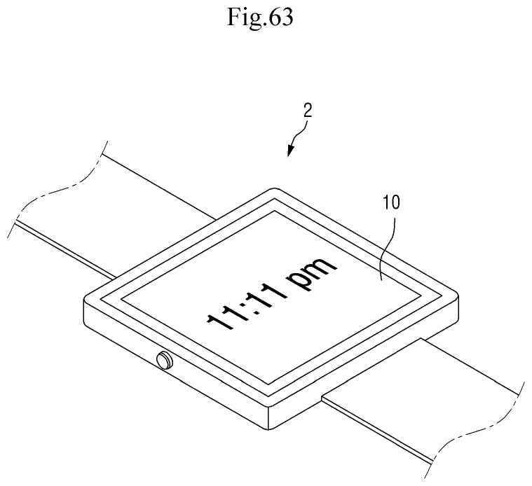

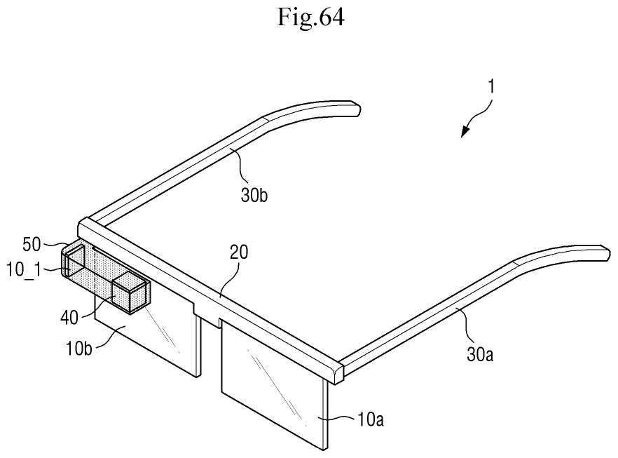

FIG. 63 is an example diagram illustrating a virtual reality device including a display device according to one or more embodiments. FIG. 64 illustrates a virtual reality device 1 in which a display device 10_1 according to one or more embodiments is used.

Referring to FIG. 64, the virtual reality device 1 according to one or more embodiments may be a device in a form of glasses. The virtual reality device 1 according to one or more embodiments may include a display device 10_1, a left-eye lens 10a, a right-eye lens 10b, a support frame 20, left and right legs 30a and 30b, a reflective member 40, and a display device housing 50.

FIG. 64 illustrates the virtual reality device 1 including the two legs 30a and 30b. However, the present disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to the example shown in FIG. 38, and may be applied in various forms and in various electronic devices.

The display device housing 50 may receive the display device 10_1 and the reflective member 40. An image displayed on the display device 10_1 may be reflected from the reflective member 40 and provided to a user's right eye through the right-eye lens 10b. Thus, the user may view a virtual reality image displayed on the display device 10_1 via the right eye.

FIG. 64 illustrates that the display device housing 50 is disposed at a right end of the support frame 20. However, the present disclosure is not limited thereto. For example, the display device housing 50 may be disposed at a left end of the support frame 20. In this case, the image displayed on the display device 10 may be reflected from the reflective member 40 and provided to the user's left eye via the left-eye lens 10a. Thus, the user may view the virtual reality image displayed on the display device 10_1 via the left eye. As another example, the display device housing 50 may be disposed at each of the left end and the right end of the support frame 20. In this case, the user may view the virtual reality image displayed on the display device 10_1 via both the left eye and the right eye.

FIG. 64 is an example diagram illustrating a smart device including a display device according to an embodiment.

Referring to FIG. 63, a display device 10 according to one or more embodiments may be applied to a smart watch 2 as one of smart devices.

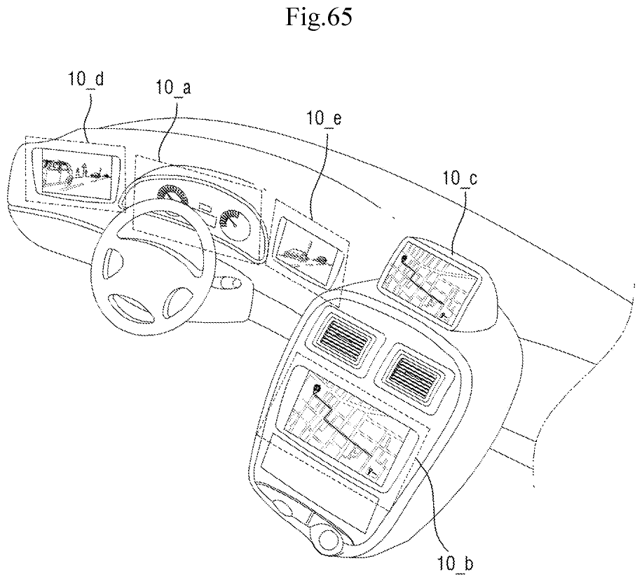

FIG. 65 is an example diagram illustrating a vehicle including a display device according to an embodiment. FIG. 65 illustrates a vehicle in which display devices according to an embodiment are used.

Referring to FIG. 65, the display devices 10_a, 10_b, and 10_c according to one or more embodiments may be applied to the dashboard of the vehicle, applied to the center fascia of the vehicle, or applied to a CID (Center Information Display) disposed on the dashboard of the vehicle. Further, each of the display devices 10_d and 10_e according to one or more embodiments may be applied to each room mirror display that replaces each of side-view mirrors of the vehicle.

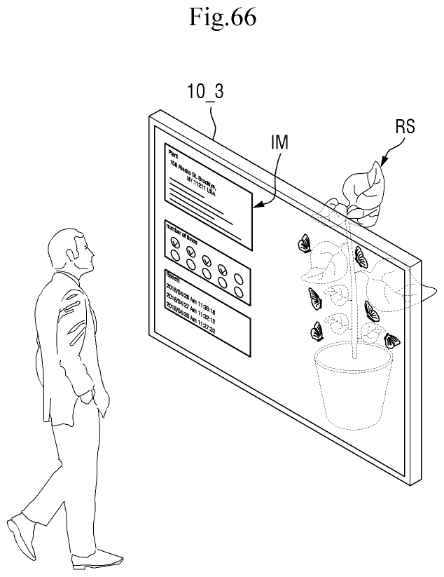

FIG. 66 is an example diagram illustrating a transparent display device including a display device according to one or more embodiments.

Referring to FIG. 66, a display device according to one or more embodiments may be applied to a transparent display device. The transparent display device 10_3 may transmit light therethrough while displaying an image IM thereon. Therefore, a user located in front of the transparent display device may not only view the image IM displayed on the display device 10_3, but also view an object RS or a background located in rear of the transparent display device. In case that the display device 10_3 is applied to the transparent display device, the first substrate 110 of the display device 10 shown in FIG. 5 may include a light transmitting portion that may transmit light therethrough or may be made of a material that may transmit light therethrough.

In concluding the detailed description, those skilled in the art will appreciate that many variations and modifications can be made to the embodiments without substantially departing from the spirit and scope of the present disclosure. Therefore, the embodiments of the present disclosure are used in a generic and descriptive sense only and not for purposes of limitation.

What is claimed is:

1. A display device comprising:
a semiconductor circuit substrate having a display area and a non-display area and comprising a plurality of pixel circuit units; and
a plurality of light emitting element layers comprising two or more layers stacked on the display area of the semiconductor circuit substrate, each of the two or more layers comprising a plurality of light emitting elements,
wherein the plurality of light emitting elements at a same layer of the plurality of light emitting element layers is configured to emit a same color light and the light emitting elements at different layers of the plurality of light emitting element layers are configured to emit different color lights, and
wherein the plurality of light emitting elements at the same layer of the plurality of light emitting element layers is connected to a same common electrode and the light emitting elements at the different layers of the plurality of light emitting element layers is connected to different common electrodes.

2. The display device of claim 1, further comprising:
a plurality of pixel electrodes connected to the plurality of pixel circuit units, respectively; and
contact electrodes on one surfaces of the light emitting elements and connected to the pixel electrodes.

3. The display device of claim 2, wherein each of the plurality of light emitting element layers comprises the pixel electrode, the plurality of light emitting elements on the pixel electrode, a contact electrode on one surface of each of the plurality of light emitting elements, a first insulating layer covering side surfaces of the plurality of light emitting elements between the plurality of light emitting elements, and a common electrode on upper surfaces of the light emitting elements and an upper surface of the first insulating layer.

4. The display device of claim 3, wherein the common electrode is on upper surfaces of the plurality of light emitting elements of the same layer.

5. The display device of claim 3, further comprising a second insulating layer between the plurality of light emitting element layers.

6. The display device of claim 5, wherein the first insulating layer and the second insulating layer include openings overlapping upper surfaces of the light emitting elements located therebelow, and
wherein a width of the openings is greater than a width of the light emitting elements.

7. The display device of claim 5, wherein the pixel electrodes are electrically connected to corresponding pixel circuit units through contact holes in the first insulating layer and the second insulating layer located below the pixel electrodes.

8. The display device of claim 7, wherein protective electrodes are on the contact holes in the insulating layers located below the pixel electrodes, and
wherein the pixel electrodes cover the protective electrodes.

9. The display device of claim 8, wherein the protective electrode has an etching selectivity different from that of the pixel electrode and comprises a conductive material.

10. The display device of claim 3, wherein the contact electrode is on the pixel electrode.

11. The display device of claim 3, wherein the light emitting elements are randomly arranged on the pixel electrode.

12. The display device of claim 3, wherein the pixel electrode is in contact with side surfaces of the contact electrode.

13. The display device of claim 12, wherein the contact electrode protrudes outward of the light emitting element in a first direction, and
wherein the pixel electrode covers the contact electrode protruding outward.

14. The display device of claim 1, wherein the common electrodes at the different layers are connected to each other, are separated from each other, or are partially connected to each other in the non-display area.

15. A display device comprising:
a semiconductor circuit substrate comprising a plurality of pixel circuit units;
a first insulating layer on a display area of the semiconductor circuit substrate;
a first light emitting element layer comprising a first pixel electrode, a first light emitting element configured to emit first light, and a first common electrode that are sequentially arranged on the first insulating layer;
a second insulating layer on the first light emitting element layer; and
a second light emitting element layer comprising a second pixel electrode, a second light emitting element configured to emit second light, and a second common electrode that are sequentially arranged on the second insulating layer.

16. The display device of claim 15, further comprising:
a third insulating layer on the second light emitting element layer;
a third light emitting element layer comprising a third pixel electrode, a third light emitting element configured to emit third light, and a third common electrode that are sequentially arranged on the third insulating layer; and
a fourth insulating layer on the third light emitting element layer.

17. The display device of claim 16, wherein the first insulating layer includes contact holes overlapping the first pixel electrode, the second pixel electrode, and the third pixel electrode and penetrating through the first insulating layer,
wherein the second insulating layer includes contact holes overlapping the second pixel electrode and the third pixel electrode and penetrating through the second insulating layer,
wherein the third insulating layer includes a contact hole overlapping the third pixel electrode and penetrating through the third insulating layer, and
wherein the display device further comprises first protective electrodes on the first insulating layer and covering the contact holes penetrating through the first insulating layer, second protective electrodes on the second insulating layer and covering the contact holes penetrating through the second insulating layer, and a third protective electrode on the third insulating layer and covering the contact hole penetrating through the third insulating layer.

18. A method of fabricating a display device, the method comprising:
forming a first insulating layer on a semiconductor circuit substrate, the first insulating layer having contact holes and the semiconductor circuit substrate having a plurality of pixel circuit units;
forming a first light emitting element layer comprising a first pixel electrode, a first light emitting element configured to emit first light, and a first common electrode that are sequentially arranged on the first insulating layer;
forming a second insulating layer on the first light emitting element layer; and
forming a second light emitting element layer comprising a second pixel electrode, a second light emitting element configured to emit second light, and a second common electrode that are sequentially arranged on the second insulating layer.

19. The method of fabricating a display device of claim 18, further comprising:
forming a third insulating layer on the second light emitting element layer;
forming a third light emitting element layer comprising a third pixel electrode, a third light emitting element configured to emit third light, and a third common electrode that are sequentially arranged on the third insulating layer; and
forming a fourth insulating layer on the third light emitting element layer.

20. The method of fabricating a display device of claim 18, wherein the forming of the first light emitting element layer comprises:
forming first protective electrodes on the first insulating layer, the first protective electrodes covering the contact holes and being connected to the pixel circuit units;
applying a pixel electrode material onto the first insulating layer on which the first protective electrodes are formed;
bonding a base substrate on which the first light emitting elements are formed to the semiconductor circuit substrate and separating the base substrate;
forming a pixel electrode in contact with the first light emitting element of a first emission area through a photoresist process;
forming a fourth insulating layer covering the pixel electrode and side surfaces of the first light emitting element; and
forming the first common electrode covering the fourth insulating layer and an upper surface of the first light emitting element

21. The method of fabricating a display device of claim 20, wherein the forming of the fourth insulating layer, a contact hole penetrating through the fourth insulating layer is formed, and
wherein in the forming of the first common electrode, a first bridge electrode covering the contact hole penetrating through the fourth insulating layer is formed, the first bridge electrode comprising a same material as the first, second, and third common electrodes and spaced from the first, second, and third common electrodes.

22. The method of fabricating a display device of claim 20, wherein the protective electrode has an etching selectivity different from that of the pixel electrode and comprises a conductive material.

23. The method of fabricating a display device of claim 18, wherein the forming of the first light emitting element layer comprises:
forming a sacrificial layer on the first insulating layer by covering the contact holes of a second emission area and a third emission area with a sacrificial material;
bonding a base substrate on which the first light emitting elements are formed to the semiconductor circuit substrate and separating the base substrate;
removing the sacrificial material;
forming a pixel electrode and connection electrodes through a photoresist process, the pixel electrode in contact with the first light emitting element of a first emission area on side surfaces of the first light emitting element and the connection electrodes covering the contact holes of the second emission area and the third emission area;
forming a fourth insulating layer covering the pixel electrode, the connection electrodes, and the side surfaces of the first light emitting element; and
forming the first common electrode covering the fourth insulating layer and an upper surface of the first light emitting element.
